(19) United States
(12) Patent Application Publication
(10) Pub. No.: US 2025/0022985 A1
(43) Pub. Date: Jan. 16, 2025

(54) LIGHT EMITTING ELEMENT ARRAY, DISPLAY DEVICE AND MANUFACTURING METHOD OF DISPLAY DEVICE

(71) Applicant: Samsung Display Co., LTD., Yongin-si (KR)

(72) Inventors: Jin Seok PARK, Yongin-si (KR); Moon Jung AN, Yongin-si (KR); Hoo Keun PARK, Yongin-si (KR)

(73) Assignee: Samsung Display Co., LTD., Yongin-si (KR)

(21) Appl. No.: 18/440,136

(22) Filed: Feb. 13, 2024

(30) Foreign Application Priority Data
Jul. 11, 2023 (KR) 10-2023-0089828

(51) Int. Cl. H01L 33/38; H01L 25/16; H01L 33/40; H01L 33/62

(52) U.S. Cl. CPC H01L 33/38; H01L 25/167; H01L 33/62; H01L 33/40; H01L 2933/0016

(57) ABSTRACT

The disclosure provides a light emitting element array, a display device, and a method of manufacturing the display device. A light emitting element array includes a base substrate, each of a plurality of light emitting elements including a light emitting element rod including a third semiconductor layer, a second semiconductor layer, a light emitting layer, and a first semiconductor layer sequentially stacked on the base substrate and an insulating layer surrounding the light emitting element rod and a connection electrode disposed on the first semiconductor layer of each of the plurality of light emitting elements, wherein a diameter of the connection electrode is greater than a diameter of the light emitting element, and the connection electrode surrounds a side surface of the first semiconductor layer and a side surface of the light emitting layer.

### CROSS-REFERENCE TO RELATED APPLICATION(S)

This application claims priority to and benefits of Korean Patent Application No. 10-2023-0089828 under 35 U.S.C. § 119, filed on Jul. 11, 2023, in the Korean Intellectual Property Office, the entire contents of which are herein incorporated herein by reference.

### BACKGROUND

### 1. Technical Field

Embodiments relate to a light emitting element array, a display device, and a method of manufacturing the display device.

### 2. Description of the Related Art

Light emitting diodes (LEDs) are characterized by their low power consumption and environmental friendliness. These advantages have led to a growing industrial demand. Light emitting elements are applied not only used in lighting devices or LCD backlights, but also in light emitting device display devices. For example, display devices using micro-unit light emitting elements are being developed. In manufacturing a micro light emitting element display device, it is necessary to transfer the micro light emitting element to a substrate.

### SUMMARY

Aspects and features of embodiments provide a method of depositing a connection electrode of a light emitting element without a patterning process using a photomask, a light emitting element array formed by the method, and a display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, a light emitting element array may include a base substrate, a plurality of light emitting elements, each of the plurality of light emitting elements including a light emitting element rod including a third semiconductor layer, a second semiconductor layer, a light emitting layer, and a first semiconductor layer sequentially stacked on the base substrate; and an insulating layer surrounding the light emitting element rod and a connection electrode disposed on the first semiconductor layer of each of the plurality of light emitting elements, wherein a diameter of the connection electrode may be greater than a diameter of the light emitting element, and the connection electrode may surround a side surface of the first semiconductor layer and a side surface of the light emitting layer.

The connection electrode may include a first portion disposed on the first semiconductor layer and a second portion disposed on a side surface of the light emitting element rod, and the first portion of the connection electrode may be convex upward.

A diameter of the second portion of the connection electrode may be changed according to a height of the second portion.

A diameter of the second portion of the connection electrode may be substantially constant according to a height of the second portion.

The connection electrode may include a first portion disposed on the first semiconductor layer and a second portion disposed on a side surface of the light emitting element rod, the first portion of the connection electrode may have a flat upper surface, and a diameter of the second portion of the connection electrode may be changed according to a height of the second portion.

The connection electrode may include a first portion disposed on the first semiconductor layer and a second portion disposed on a side surface of the light emitting element rod, the first portion of the connection electrode may have a flat upper surface, and a diameter of the second portion of the connection electrode may be substantially constant according to a height of the second portion.

Each of the plurality of light emitting elements may have at least one of a circular shape, a hexagonal shape, and a rectangular shape in a plan view.

According to an embodiment, a display device may include a substrate including a pixel electrode, a plurality of light emitting elements, each of the plurality of light emitting elements including a light emitting element rod including a first semiconductor layer, a light emitting layer, and a second semiconductor layer sequentially stacked on the pixel electrode of the substrate, and an insulating layer surrounding the light emitting element rod, a connection electrode disposed between the pixel electrode and the plurality of light emitting elements and a common electrode disposed on the light emitting element, wherein a diameter of the connection electrode is greater than a diameter of the light emitting element, and the connection electrode may surround a side surface of the first semiconductor layer and a side surface of the light emitting layer.

The connection electrode may include a first portion disposed on the first semiconductor layer and a second portion disposed on a side surface of the light emitting element rod, and a diameter of the second portion of the connection electrode may be changed according to a height of the second portion.

The connection electrode may include a first portion disposed on the first semiconductor layer and a second portion disposed on a side surface of the light emitting element rod, and a diameter of the second portion of the connection electrode may be substantially constant according to a height of the second portion.

Each of the plurality of light emitting elements may have at least one of a circular shape, a hexagonal shape, and a rectangular shape in a plan view.

The connection electrode may include at least one of gold (Au), copper (Cu), tin (Sn), silver (Ag), aluminum (Al), and titanium (Ti).

According to an embodiment, a method of manufacturing a light emitting element may include forming a light emitting element rod including a third semiconductor layer, a second semiconductor layer, a light emitting layer, and a first semiconductor layer sequentially stacked on a base substrate, forming an insulating layer surrounding the light emitting element rod and forming a connection electrode having a diameter larger than a diameter of the light emitting element and surrounding a portion of a side surface of the light emitting element rod on a substrate on which the light emitting element rod is formed.

The forming of the connection electrode may be performed by at least one of an electron beam evaporation method, a sputtering method, and a molecular beam epitaxy (MBE) method.

The connection electrode may surround a side surface of the first semiconductor layer and a side surface of a light emitting layer.

The method may further include aligning the light emitting element on which the connection electrode is formed on a substrate on which a pixel electrode is formed, bonding the connection electrode to the pixel electrode, removing the base substrate and the third semiconductor layer and forming a common electrode on the light emitting element.

The connection electrode may include a first portion disposed on the first semiconductor layer and a second portion disposed on a side surface of the light emitting element rod, and a diameter of the second portion may be changed according to a height of the second portion.

The connection electrode may include a first portion disposed on the first semiconductor layer and a second portion disposed on a side surface of the light emitting element rod, and a diameter of the second portion of the connection electrode may be substantially constant according to a height of the second portion.

The light emitting element may have at least one of a circular shape, a hexagonal shape, and a rectangular shape in a plan view.

The connection electrode may include at least one of gold (Au), copper (Cu), tin (Sn), silver (Ag), aluminum (Al), and titanium (Ti).

The display device according to an embodiment may improve shot spot.

Further, light emitting efficiency may be improved by forming a connection electrode to surround the light emitting layer of the light emitting element.

However, the effects of the disclosure are not limited to the aforementioned effects, and various other effects are included in the disclosure.

### BRIEF DESCRIPTION OF THE DRAWINGS

FIG. 1 is a drawing to illustrate an exposure method used in manufacturing process of a light emitting element array.

FIG. 2 is a schematic plan view to illustrate an overlap region of shots in a manufacturing process of a light emitting element array.

FIG. 3 is a schematic plan view of a light emitting element array according to an embodiment.

FIG. 4 is a schematic plan view of a light emitting element array according to another embodiment.

FIG. 5 is a schematic plan view of a light emitting element array according to another embodiment.

FIG. 6 is a schematic cross-sectional view taken along A-A′ of FIG. 3 according to an embodiment.

FIGS. 7, 8, and 9 are schematic cross-sectional views taken along A-A′ of FIG. 3 according to another embodiment.

FIG. 10 is a schematic plan view of a display device according to an embodiment.

FIG. 11 is a schematic layout view of a display substrate circuit of a display device according to an embodiment.

FIG. 12 is a schematic diagram of an equivalent circuit of a pixel of a display device according to an embodiment.

FIG. 13 is a schematic diagram of an equivalent circuit of a pixel of a display device according to another embodiment.

FIG. 14 is a schematic diagram of an equivalent circuit of a pixel of a display device according to another embodiment.

FIG. 15 is a schematic cross-sectional view of a display device according to an embodiment.

FIG. 16 is an enlarged schematic view of region B shown in FIG. 15 according to an embodiment.

FIG. 17 is a schematic plan view illustrating light emitting regions of a display device.

FIG. 18 is an enlarged schematic view of region B shown in FIG. 15 according to another embodiment.

FIG. 19 is a graph to illustrate the reflectivity of a connection electrode according to an embodiment.

FIG. 20 is a SEM picture taken with a scanning electron microscope of a light emitting element according to an embodiment.

FIG. 21 is a flowchart to illustrate steps of a method of manufacturing the display device according to an embodiment.

FIGS. 22, 23, 24, 25, 26, 27, 28, and 29 are diagrams to illustrate the steps of FIG. 21.

FIG. 30 is an example diagram schematically showing a virtual reality device including a display device according to an embodiment.

FIG. 31 is an example diagram schematically showing a smart device including a display device according to an embodiment.

FIG. 32 is a diagram of an example schematically showing a vehicle including a display device according to an embodiment.

FIG. 33 is a diagram of an example schematically showing a transparent display device including a display device according to an embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for case of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

In manufacturing the light emitting element, a connection electrode to be described later may be formed by a mask process.

The mask process may include the following processes.

First, a metal film may be deposited on the entire surface of the substrate by chemical vapor deposition (CVD) or sputtering to form a deposited film.

Then, the surface of the deposited film formed on the substrate may be cleaned, a photoresist may be coated, and a certain pattern shape may be formed by exposure and development processes using a mask.

Then, using the patterned photoresist film as a mask, the deposited film may be etched to form a certain pattern, and then the patterned photoresist film may be removed to complete a mask process.

Hereinafter, embodiments will be described with reference to the accompanying drawings.

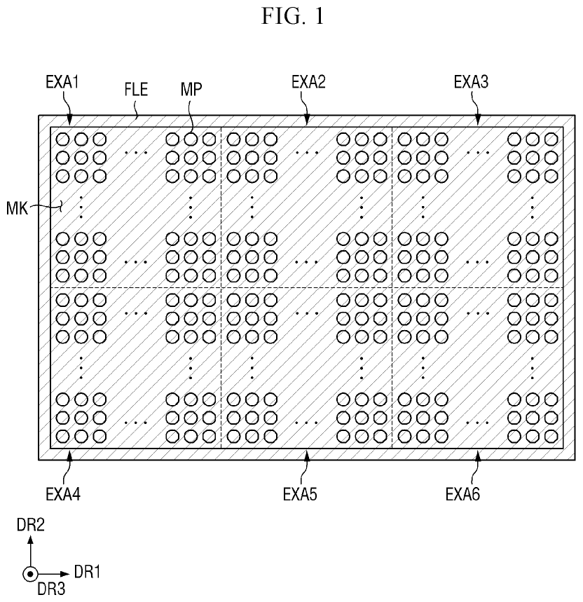

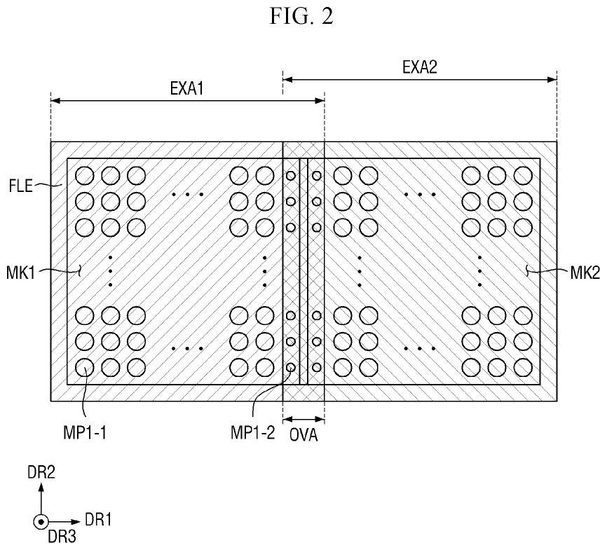

FIG. 1 is a drawing to illustrate an exposure method used in manufacturing process of a light emitting element array. FIG. 2 is a schematic plan view to illustrate an overlap region of shots in a manufacturing process of a light emitting element array.

In an embodiment, a connection electrode BOL of the light emitting element LE may be formed by performing a mask process.

For example, the mask process may be performed by depositing a mask on a substrate, applying a photoresist film, and performing exposure treatment according to a pattern of the mask. At this time, the mask process may not be completed in a single exposure due to the disadvantage that the production cost increases as the exposure lens becomes larger. Therefore, divisional exposure may be performed.

In an embodiment, the entire surface of the substrate to be exposed is called a field, and a certain area where a certain pattern is transferred with one exposure through a reticle is called a shot.

Referring to FIG. 1, a field FLE may request shots EXA1, EXA2, EXA3, EXA4, EXA5, and EXA6. A mask MK may include a pattern MP. The size of the mask MK may be the same as the size of the shot.

Referring to FIG. 2, a first exposure may be performed on the first shot area EXA1 on the left side of the field FLE having a certain width, and then, a second exposure may be performed on the second shot area EXA2 adjacent to the first shot area EXA1. In case that the mask MK (e.g., MK1 and MK2) is repeatedly exposed to the field FLE, an overlapping area OVA may occur in which the adjacent shots EXA1 and EXA2 overlap each other. For example, the mask MK (e.g., MK1 and MK2) may be a negative photoresist mask. For example, a photoresist may be a chemical substance whose characteristics change in response to light (e.g., photosensitization). Negative photoresist may be characterized by dissolving the unlit areas. Accordingly, the mask MK (e.g., MK1 and MK2) for negative photoresist may block light in a portion where the pattern MP (e.g., MP1-1 and MP1-2) is to be formed.

An abnormal pattern MP1-2 having a different size than the normal pattern MP1-1 may occur in the overlap area OVA.

For example, the abnormal pattern MP1-2 may occur in case that the shots are not exactly aligned due to distortion such as transition, rotation, twist, etc. For example, the discontinuity between the two shots may cause a stitch defect on the screen of the corresponding display device.

Therefore, in an embodiment, a photoresist patterning method using the mask MK may not be adopted in the manufacturing process of the light emitting device array, and a front deposition method may be used.

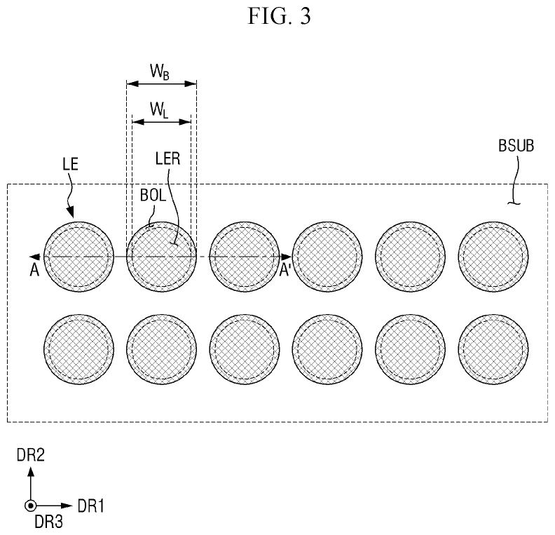

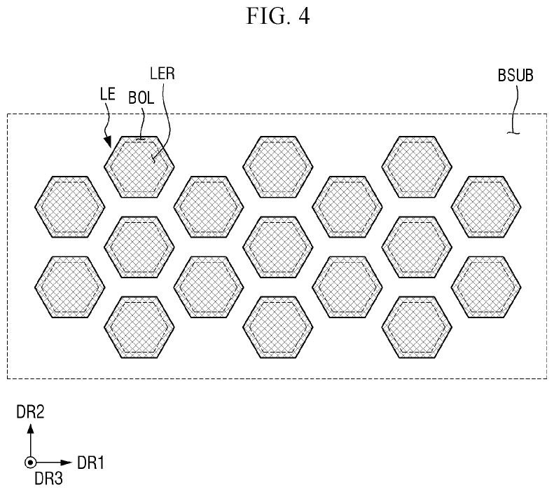

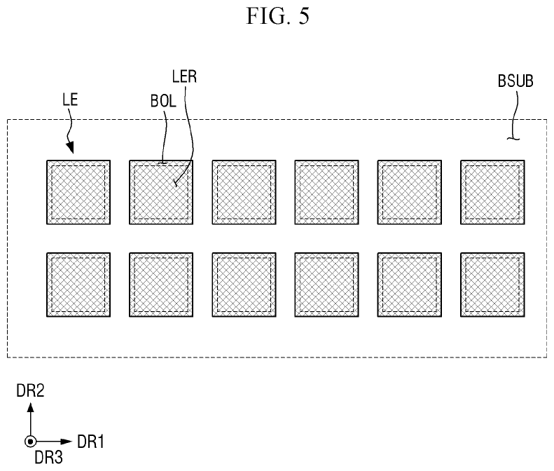

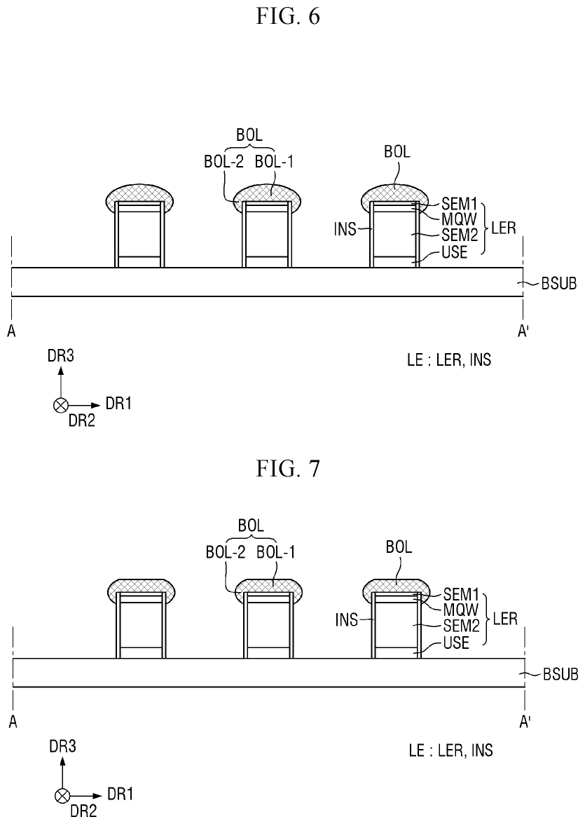

FIG. 3 is a schematic plan view of a light emitting element array according to an embodiment. FIG. 4 is a schematic plan view of a light emitting element array according to another embodiment. FIG. 5 is a schematic plan view of a light emitting element array according to another embodiment. FIG. 6 is a schematic cross-sectional view taken along A-A′ of FIG. 3 according to an embodiment. FIGS. 7 to 9 are schematic cross-sectional views taken along A-A′ of FIG. 3 according to another embodiment.

Although the light emitting element LE according to an embodiment has been described as being a miniature light emitting diode display device (e.g., micro or nano light emitting diode display device) including a miniature light emitting diode (e.g., micro or nano light emitting diode), embodiments are not limited thereto.

Referring to FIG. 3, light emitting elements LE may be arranged in a first direction DR1 and a second direction DR2 on a base substrate BSUB according to an embodiment. The light emitting elements LE may be spaced apart from each other at equal intervals.

The base substrate BSUB may have a rectangular planar shape. However, the planar shape of the base substrate BSUB is not limited thereto, and may have a polygonal, circular, elliptical, or irregular planar shape other than the rectangular.

The base substrate BSUB may be a sapphire substrate (Al₂O₃) or a silicon wafer including silicon. However, embodiments are not limited thereto, and in an embodiment, a case where the base substrate BSUB is the sapphire substrate will be described as an example.

The light emitting element LE may be a vertical light emitting diode element extending longitudinally in the third direction DR3. For example, the length of the light emitting element LE in the third direction DR3 may be longer than the length (or width/diameter) of the light emitting element LE in the horizontal direction. The length (or width/diameter) in the horizontal direction refers to the length (or width/diameter) in the first direction DR1 or the length (or width/diameter) in the second direction DR2.

The light emitting element LE may have a circular planar shape. As shown in FIG. 4, the light emitting element LE may have a hexagonal planar shape, and as shown in FIG. 5, the light emitting element LE may have a quadrangular planar shape.

However, embodiments are not limited thereto. For example, the light emitting element LE may have a polygonal shape such as a triangle, a quadrangle, a pentagon, a hexagon, and an octagon, an ellipse, or an irregular planar shape.

Referring to FIGS. 3 to 5, the planar shape of the connection electrode BOL may be formed according to the planar shape of the light emitting element LE. For example, in case that the planar shape of the light emitting element LE is circular, the planar shape of the connection electrode BOL may be also circular, in case that the planar shape of the light emitting element LE is hexagonal, the planar shape of the connection electrode BOL may be also hexagonal, and in case that the planar shape of the light emitting element LE is a square, the planar shape of the connection electrode BOL may also be a square.

The connection electrode BOL may be disposed on the upper surface of the light emitting element LE.

A diameter W_{B} of the connection electrode BOL may be larger than the diameter W_{L} of the light emitting element LE.

Referring to FIG. 6, the light emitting element LE may be a micro light emitting diode element. The light emitting element LE may include a third semiconductor layer USE, a second semiconductor layer SEM2, a light emitting layer MQW, a first semiconductor layer SEM1, an insulating layer INS, and the connection electrode BOL in the thickness direction of the base substrate BSUB, e.g., the third direction DR3. The third semiconductor layer USE, the second semiconductor layer SEM2, the light emitting layer MQW, and the first semiconductor layer SEM1 may be sequentially stacked in the third direction DR3. For convenience of description, the third semiconductor layer USE, the second semiconductor layer SEM2, the light emitting layer MQW, and the first semiconductor layer SEM1 stacked in the third direction DR3 are referred to as light emitting element rod LER.

The light emitting element LE may have a cylindrical shape, a disk shape, or a rod shape with a diameter longer than a height. However, the light emitting element LE is not limited thereto, and the light emitting element LE may have a shape such as a rod, a wire, a tube, or a polygonal column shape such as a regular hexahedron, a rectangular parallelepiped, or hexagonal prism or a shape extending in a direction but having a partially inclined outer surface.

The third semiconductor layer USE may be disposed on the base substrate BSUB.

The third semiconductor layer USE may be undoped.

The second semiconductor layer SEM2 may be disposed on the third semiconductor layer USE. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the second semiconductor layer SEM2 may be any one or more of n-type doped AlGalnN, GaN, AlGaN, InGaN, AlN, and InN. The second semiconductor layer SEM2 may be doped with an n-type dopant, and the n-type dopant may be Si, Ge, or Sn. For example, the second semiconductor layer SEM2 may be n-GaN doped with n-type Si. The thickness of the second semiconductor layer SEM2 may range from about 2 μm to about 4 μm, but embodiments are not limited thereto.

The light emitting layer MQW may emit light by combining electron-hole pairs according to electrical signals applied through the first semiconductor layer SEM1 and the second semiconductor layer SEM2. The light emitting layer MQW may emit first light having a central wavelength range of about 450 nm to about 495 nm, e.g., light in a blue wavelength band.

The light emitting layer MQW may include a single quantum well structure or a multiple quantum well structure. In case that the light emitting layer MQW includes a material with a multi-quantum well structure, it may be a stacked structure with well layers and a barrier layer alternately stacked with each other. For example, the well layers may be formed of InGaN and the barrier layer may be formed of GaN or AlGaN, but embodiments are not limited thereto. The thickness of each of the well layers may be about 1 nm to about 4 nm, and the thickness of the barrier layer may be about 3 nm to about 10 nm.

The light emitting layer MQW may have a structure in which a semiconductor material having a large band gap energy and a semiconductor material having a small band gap energy are alternately stacked with each other and may include other Group 3 to Group 5 semiconductor materials according to the wavelength band of the emitted light. The light emitted from the light emitting layer MQW is not limited to the first light (e.g., light in the blue wavelength band) and may emit second light (e.g., light in the green wavelength band) or third light (e.g., light in the red wavelength band) in some cases. In an embodiment, in case that semiconductor materials included in the light emitting layer MQW include indium, the color of emitted light may vary according to the amount of indium. For example, in case that the content of indium is about 15%, light in a blue wavelength band may be emitted, in case that the content of indium is about 25%, light in a green wavelength band may be emitted, and in case that the content of indium is about 35% or more, light in a red wavelength band may be emitted.

The first semiconductor layer SEM1 may be doped with a first conductivity type dopant such as Mg, Zn, Ca, Se, or Ba. For example, the first semiconductor layer SEM1 may be p-GaN doped with p-type Mg. The thickness of the first semiconductor layer SEM1 may be about 30 nm to about 200 nm, but embodiments are not limited thereto.

In another embodiment, a superlattice layer may be disposed between the second semiconductor layer SEM2 and the light emitting layer MQW. The superlattice layer may be a layer to relieve stress between the second semiconductor layer SEM2 and the light emitting layer MQW. For example, the superlattice layer may be formed of InGaN or GaN. A thickness of the superlattice layer may be about 50 nm to about 200 nm. In another example, the superlattice layer may be omitted.

In another embodiment, an electron blocking layer may be further disposed between the first semiconductor layer SEM1 and the light emitting layer MQW. The electron blocking layer may be a layer for suppressing or preventing too many electrons from flowing into the light emitting layer MQW. For example, the electron blocking layer may be p-AlGaN doped with p-type Mg. The thickness of the electron blocking layer may be about 10 nm to about 50 nm. In another example, the electron blocking layer may be omitted.

The insulating layer INS may surround a side surface of the light emitting element LE, for example, an outer circumferential surface. The insulating layer INS may surround the light emitting element rod LER.

The insulating layer INS may insulate the light emitting elements LE from the outside. The insulating layer INS may be disposed (e.g., directly disposed) on outer circumferential surfaces of the third semiconductor layer USE, the second semiconductor layer SEM2, the light emitting layer MQW, and the first semiconductor layer SEM1 to surround them. In an embodiment, the insulating layer INS may surround the entire outer circumferential surfaces of the third semiconductor layer USE, the second semiconductor layer SEM2, the light emitting layer MQW, and the first semiconductor layer SEM1.

The insulating layer INS may expose end portions (e.g., opposite end portions) of the light emitting element LE.

The insulating layer INS may include an inorganic insulating material such as silicon oxide (SiOₓ), silicon nitride (SiNₓ), silicon oxynitride (SiOₓN_{y}), aluminum oxide (AlₓO_{y}), or aluminum nitride (AlN). A thickness of the insulating layer INS may be about 0.1 μm, but embodiments are not limited thereto.

The connection electrode BOL may be disposed on the light emitting element LE. In an embodiment, the connection electrode BOL may be disposed on the first semiconductor layer SEM1. The connection electrode BOL may surround side surfaces of the first semiconductor layer SEM1 and the light emitting layer MQW.

The connection electrode BOL may include a first portion BOL-1 disposed on the first semiconductor layer SEM1 and a second portion BOL-2 surrounding side surfaces of the first semiconductor layer SEM1 and the light emitting layer MQW. The first portion BOL-1 and the second portion BOL-2 may have an upwardly convex shape.

The height of the second portion BOL-2 may be in a range of about 1 μm to about 2 μm, but embodiments are not limited thereto. The height of the second portion BOL-2 refers to the length of the light emitting element rod LER in the third direction DR3.

The thickness of the second portion BOL-2 may be different according to the height. For example, a middle part of the second portion BOL-2 may be formed to be the thickest. In another embodiment, the second portion BOL-2 may be formed thinner towards the bottom.

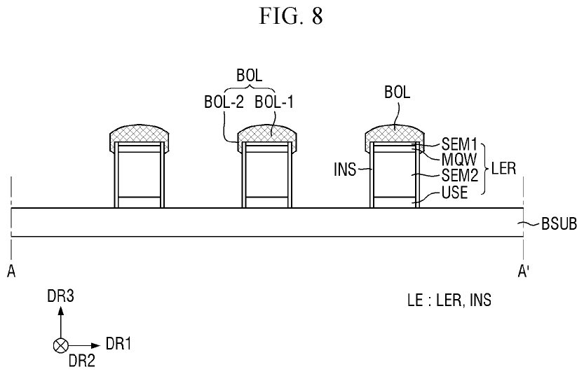

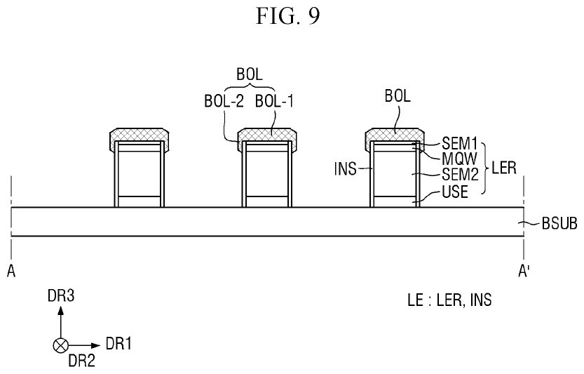

In another embodiment, referring to FIGS. 7 to 9, at least a part of the first portion BOL-1 and the second portion BOL-2 may have a flat shape. For example, as shown in FIG. 7, the first portion BOL-1 may have a flat shape, and the second portion BOL-2 may have an upwardly convex shape. As shown in FIG. 8, the first portion BOL-1 may have an upwardly convex shape, and the second portion BOL-2 may have a flat shape. As shown in FIG. 9, both the first portion BOL-1 and the second portion BOL-2 may have a flat shape.

The connection electrode BOL may include a conductive material and function to transfer a light emitting signal from an external, e.g., pixel electrode, to the light emitting element LE. The connection electrode BOL may include at least one of gold (Au), copper (Cu), tin (Sn), silver (Ag), aluminum (Al), and titanium (Ti). For example, the connection electrode BOL may include a 9:1 alloy of gold and tin, an 8:2 alloy, or a 7:3 alloy, or may include an alloy of copper, silver, and tin (e.g., SAC305).

The side of the light emitting element LE shown in FIGS. 6 to 9 may have an angle of 90 degrees or less with the base substrate BSUB on which the light emitting element LE is not disposed.

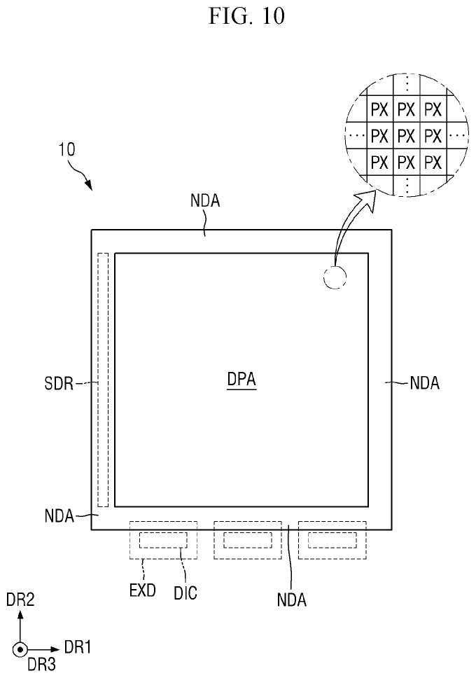

FIG. 10 is a schematic plan view of a display device according to an embodiment.

Referring to FIG. 10, a display device 10 according to an embodiment may be applied to various consumer electronics, or internet of things devices, such as smartphones, cell phones, tablet PC, personal digital assistants (PDA), portable multimedia players (PMP), televisions, gaming devices, watch-type electronic devices, head-mounted displays, monitors of personal computers, laptop computers, car navigation, car instrument panels, digital cameras, camcorders, exterior billboards, billboards, medical devices, inspection devices, refrigerators, and washing machines, and the like. A television is described herein as an example of the display device, and the television may have a high or ultra-high resolution, such as HD, UHD, 4K, 8K, etc.

For example, in the following drawings, a first direction DR1 refers to a horizontal direction of the display device 10, a second direction DR2 refers to a vertical direction of the display device 10, and a third direction DR3 refers to a thickness direction of the display device 10. For example, “left”, “right”, “top”, and “bottom” refer to directions when the display device 10 is viewed from a plane. For example, “right” refers to a side of the first direction DR1, “left” refers to the other side of the first direction DR1, “top” refers to a side of the second direction DR2, and “bottom” refers to the other side of the second direction DR2. Further, “upper” refers to a first side of the third direction DR3 and “lower” refers to a second side of the third direction DR3.

The display device 10 according to an embodiment may have a square shape in plan view, for example, a square shape. In case that the display device 10 is a television, it may have a rectangular shape with the long sides disposed in the transverse direction. However, embodiments are not limited thereto, the long sides may be disposed in the longitudinal direction, and it may be rotatably mounted so that the long sides may be variably disposed in the horizontal or vertical direction. The display device 10 may also have a circular or oval shape.

The display device 10 may include a display area DPA and a non-display area NDA. The display area DPA may be an active area where the video is displayed. The display area DPA may have a square shape in plan view similar to the overall shape of the display device 10, but embodiments are not limited thereto.

The display area DPA may include pixels PX. The pixels PX may be arranged in a matrix orientation. The shape of each pixel PX may be rectangular or square in plan view, but embodiments are not limited thereto, and may also be rhombic in shape with each side inclined toward a side of the display device 10. The pixels PX may include multiple color pixels PX. For example, the pixels may include a first color pixel PX of red, a second color pixel PX of green, and a third color pixel PX of blue but embodiments are not limited thereto. Each color pixel PX may be alternately arranged in a stripe-type or a pentile-type (e.g., PenTile™).

The non-display area NDA may be disposed on the periphery of the display area DPA. The non-display area NDA may fully or partially enclose (or surround) the display area DPA. The display area DPA may be square in shape, and the non-display areas NDA may be arranged to be adjacent to the four sides of the display area DPA. The non-display area NDA may include a bezel of the display device 10.

A driving circuit or a driving element for driving the display area DPA may be disposed in the non-display area NDA. In an embodiment, the non-display area NDA disposed adjacent to the first side (e.g., lower side in FIG. 1) of the display device 10 may have a pad portion disposed on the display substrate of the display device 10, and an external device EXD may be mounted on the pad electrode of the pad portion. Examples of the external device EXD include a connection film, a printed circuit board, a driving chip DIC, a connector, a wiring connection film, and the like. In the non-display area NDA disposed adjacent to the second side (left side in FIG. 1) of the display device 10, a scan driving unit SDR, or the like formed (e.g., directly formed) on the display substrate of the display device 10 may be disposed.

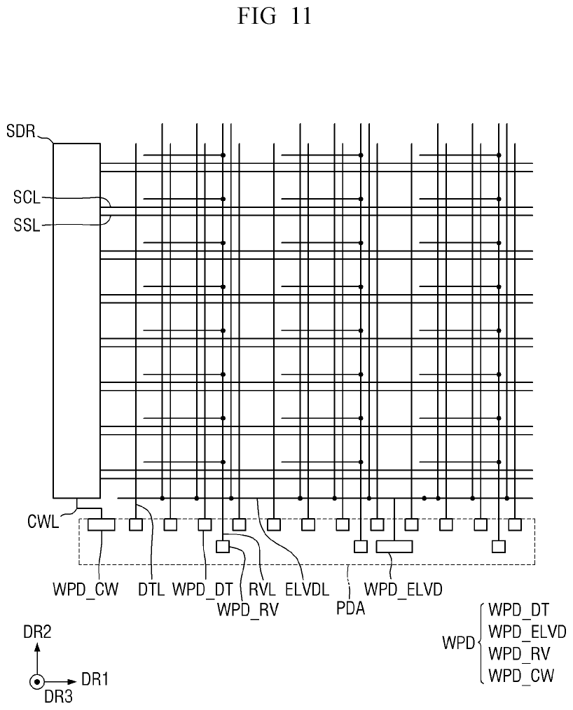

FIG. 11 is a schematic layout view of a display substrate circuit of a display device according to an embodiment.

Referring to FIG. 11, a plurality of lines may be disposed on the substrate. The plurality of lines may include a scan line SCL, a sensing signal line SSL, a data line DTL, a reference voltage line RVL, a first power supply line ELVDL, and the like.

The scan line SCL and the sensing signal line SSL may be extended in the first direction DR1. The scan line SCL and the sensing signal line SSL may be connected (e.g., electrically connected) to the scan driving unit SDR. The scan driving unit SDR may include a driving circuit. The scan driving unit SDR may be disposed on a side of the non-display area NDA on the display substrate, but may also be disposed on sides (e.g., opposite sides) of the non-display area NDA. The scan driving unit SDR may be connected (e.g., electrically connected) to a signal connection line CWL, and at least one end portion of the signal connection line CWL may be connected (e.g., electrically connected) to an external device (“EXD” in FIG. 10) by forming a pad (WPD_CW) on the first non-display area NDA and/or the second non-display area NDA.

The data line DTL and the reference voltage line RVL may be extended in the second direction DR2 intersecting the first direction DR1. The first power supply line ELVDL may include a portion extending in the second direction DR2. The first power supply line ELVDL may further include a portion extending in the first direction DR1. The first power supply line ELVDL may have a mesh structure, but embodiments are not limited thereto.

Wiring pads WPD may be disposed at at least one end portion of the data line DTL, the reference voltage line RVL, and the first power supply line ELVDL. Each wiring pad WPD may be disposed on a pad area PDA of the non-display area NDA. In an embodiment, a wiring pad WPD_DT (hereinafter referred to as a “data pad”) for a data line DTL, a wiring pad WPD_RV (hereinafter referred to as a “reference voltage pad”) for the reference voltage line RVL, and a wiring pad WPD_ELVD (hereinafter referred to as a “first power pad”) for a first power supply line ELVDL may be disposed on the pad area PDA of the non-display area NDA. In another example, the data pad WPD_DT, the reference voltage pad WPD_RV, and the first power supply pad WPD_ELVD may be disposed in different non-display areas NDA. An external device EXD in FIG. 10 may be mounted on the wiring pad WPD as described above. The external device EXD may be mounted on the wiring pad WPD through an anisotropic conductive film, ultrasonic bonding, or the like.

Each pixel PX on the display board may include a pixel driving circuit. The wiring described above may pass through or around each pixel PX and apply a driving signal to each pixel driving circuit. The pixel driving circuit may include a transistor and a capacitor. The number of transistors and capacitors in each pixel driving circuit may be varied. Hereinafter, the pixel driving circuit will be described taking a 3T1C structure including three transistors and one capacitor as an example, but embodiments are not limited thereto, and various other modified pixel PX structures such as a 2T1C structure, a 7T1C structure, and a 6T1C structure may be applied.

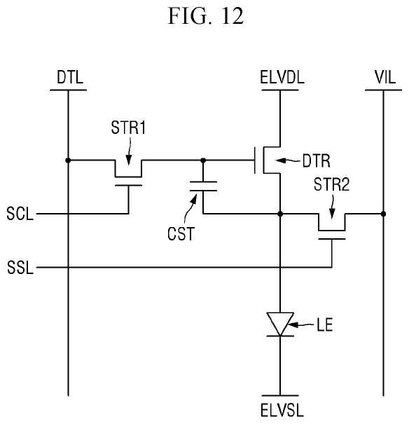

FIG. 12 is a schematic diagram of an equivalent circuit of a pixel of a display device according to an embodiment.

Referring to FIG. 12, each pixel PX of the display device according to an embodiment may include, in addition to the light emitting element LE, three transistors DTR, STR1 and STR2 and one capacitor CST for storage.

The light emitting element LE may emit light in response to a current supplied through a driving transistor DTR. The light emitting element LE may be implemented as an inorganic light emitting diode, an organic light emitting diode, a micro light emitting diode, a nano light emitting diode, or the like.

A first electrode (e.g., an anode electrode) of the light emitting element LE may be connected (e.g., electrically connected) to a source electrode of the driving transistor DTR, and a second electrode (e.g., a cathode electrode) may be connected (e.g., electrically connected) to a second power supply line ELVSL supplied with a low potential voltage (e.g., second power supply voltage) lower than a high potential voltage (e.g., first power supply voltage) of the first power supply line ELVDL.

The driving transistor DTR may adjust the current flowing to the light emitting element LE from the first power supply line ELVDL supplied with the first power voltage according to the voltage difference between a gate electrode and the source electrode. The gate electrode of the driving transistor DTR may be connected (e.g., electrically connected) to the first electrode of the first transistor STR1, the source electrode may be connected (e.g., electrically connected) to the first electrode of the light emitting element LE, and a drain electrode may be connected (e.g., electrically connected) to the first power supply line ELVDL to which the first power supply voltage is applied.

A first transistor STR1 may be turned-on by a scan signal of the scan line SCL to connect (e.g., electrically connect) the data line DTL to the gate electrode of the driving transistor DTR. The gate electrode of the first transistor STR1 may be connected (e.g., electrically connected) to the scan line SL, the first electrode may be connected (e.g., electrically connected) to the gate electrode of the driving transistor DTR, and the second electrode may be connected (e.g., electrically connected) to the data line DTL.

A second transistor STR2 may be turned-on by a sensing signal of the sensing signal line SSL to connect an initialization voltage line VIL to the source electrode of the driving transistor DTR. The gate electrode of the second transistor STR2 may be connected (e.g., electrically connected) to the sensing signal line SSL, the first electrode may be connected (e.g., electrically connected) to the initialization voltage line VIL, and the second electrode may be connected (e.g., electrically connected) to the source electrode of the driving transistor DTR.

In an embodiment, the first electrode of each of the first and second transistors STR1 and STR2 may be the source electrode and the second electrode may be the drain electrode, but embodiments are not limited thereto, and may be vice versa.

The capacitor CST may be formed between the gate and source electrodes of the driving transistor DTR. The capacitor CST may store the difference voltage between the gate voltage of the driving transistor DTR and the source voltage.

The driving transistor DTR and the first and second transistors STR1 and STR2 may be formed as thin film transistors. Furthermore, while FIG. 12 describes the driving transistor DTR and the first and second switching transistors STR1 and STR2 as being N-type MOSFET (e.g., metal oxide semiconductor field effect transistors), embodiments are not limited to thereto. For example, the driving transistor DTR and the first and second switching transistors STR1 and STR2 may be P-type MOSFET, or some may be N-type MOSFET, and others may be P-type MOSFET.

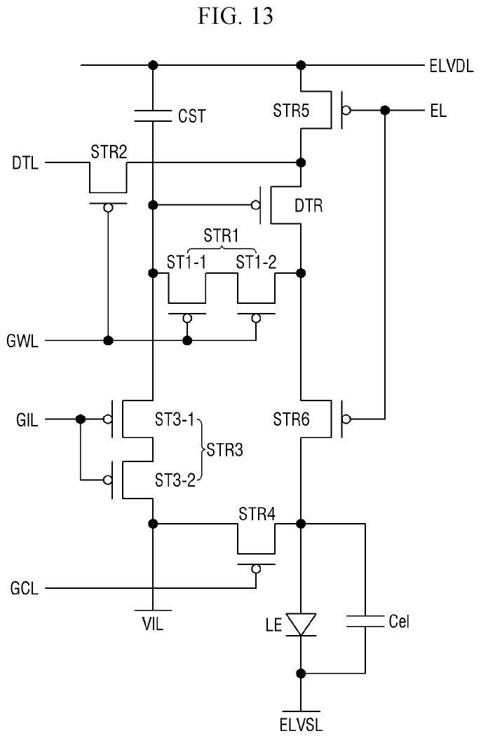

FIG. 13 is a schematic diagram of an equivalent circuit of a pixel of a display device according to another embodiment.

Referring to FIG. 13, the first electrode of the light emitting element LE may be connected (e.g., electrically connected) to the first electrode of the fourth transistor STR4 and the second electrode of the sixth transistor STR6, and the second electrode may be connected (e.g., electrically connected) to the second power supply line ELVSL. A parasitic capacity Cel may be formed between the first electrode and the second electrode of the light emitting element LE.

Each pixel PX may include the driving transistor DTR, switch elements, and the capacitor CST. The switch elements include first to sixth transistors STR1, STR2, STR3, STR4, STR5, and STR6.

For example, the first transistor STR1 may include first sub-transistors ST1-1 and ST1-2, which are connected to each other in serial. The first transistor STR1 may be turned-on by a scan signal of the write scan line GWL to diode-connect the driving transistor DTR. The second transistor STR2 may be turned-on by the scan signal of the write scan line GWL to electrically connect the data line DTL to the source electrode of the driving transistor DTR. For example, the third transistor STR3 may include third sub-transistors ST3-1 and ST3-2, which are connected to each other in serial. The third transistor STR3 may be turned-on by an initialization signal of the initialization scan line GIL such that the gate electrode of the driving transistor DTR may be electrically connected to the initialization voltage line VIL. The fourth transistor STR4 may be turned-on by a control signal of the control scan line GCL such that light emitting element LE may be electrically connected to the initialization voltage line VIL. The fifth and sixth transistors STR5 and STR6 may be turned-on by an emission control signal of an emission control scan line EL such that the current may flow into the light emitting element LE through the driving transistor DTR.

The driving transistor DTR may include the gate electrode, the first electrode, and the second electrode. The driving transistor DTR controls the drain-to-source current Ids (hereinafter referred to as the “driving current”) flowing between the first and second electrodes based on the data voltage applied to the gate electrode.

The capacitor CST may be formed between the second electrode of the driving transistor DTR and the second power supply line ELVSL. An electrode of the capacitor CST may be connected (e.g., electrically connected) to the second electrode of the driving transistor DTR, and another electrode of the capacitor CST may be connected (e.g., electrically connected) to the second power supply line ELVSL.

In case that the first electrode of each of the first to sixth transistors STR1, STR2, STR3, STR4, STR5, and STR6 and the driving transistor DTR is the source electrode, the second electrode may be the drain electrode. In another example, in case that the first electrode of each of the first to sixth transistors STR1, STR2, STR3, STR4, STR5, and STR6 and the driving transistor DTR is the drain electrode, the second electrode may be the source electrode.

An active layer of each of the first to sixth transistors STR1, STR2, STR3, STR4, STR5, and STR6 and the driving transistor DTR may be formed of any of poly silicon, amorphous silicon, and oxide semiconductors. In case that the semiconductor layer of each of the first through sixth transistors STR1, STR2, STR3, STR4, STR5, and STR6 and the driving transistor DTR is formed of poly silicon, the process for forming it may be a low temperature poly silicon (LTPS) process.

For example, in FIG. 13, the first to sixth transistors STR1, STR2, STR3, STR4, STR5, and STR6 and the driving transistor DTR may be described centering on the P-type MOSFET (Metal Oxide Semiconductor Field Effect Transistor), but embodiments are not limited thereto, and may be formed as the N-type MOSFET.

Further, the first power supply voltage of the first power supply line ELVDL, the second power supply voltage of the second power supply line ELVSL, and the third power supply voltage of the third power supply line VIL may be set by considering the characteristics of the driving transistor DTR, the characteristics of the light emitting element LE, and the like.

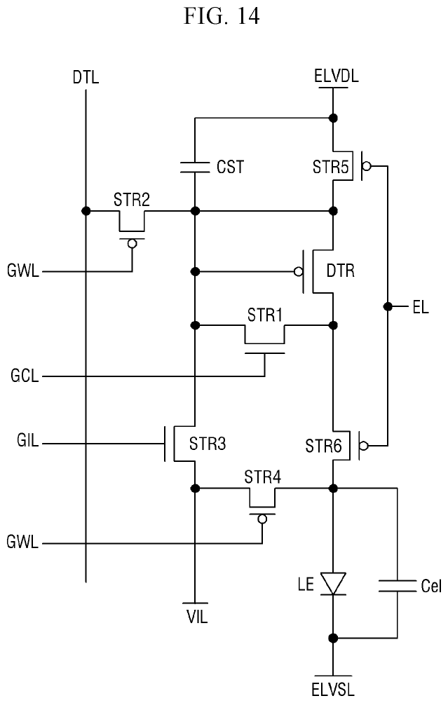

FIG. 14 is a schematic diagram of an equivalent circuit of a pixel of a display device according to another embodiment.

The embodiment of FIG. 14 differs from the embodiment of FIG. 13 in that the driving transistor DTR, the second transistor STR2, the fourth transistor STR4, the fifth transistor STR5, and the sixth transistor STR6 are formed as the P-type MOSFET, and the first transistor STR1 and the third transistor STR3 are formed as the N-type MOSFET.

Referring to FIG. 14, the active layer of each of the driving transistor DTR, second transistor STR2, fourth transistor STR4, fifth transistor STR5, and sixth transistor STR6 formed as the P-type MOSFET may be formed of polysilicon, and the active layer of each of the first transistor STR1 and third transistor STR3 formed as the N-type MOSFET may be formed of an oxide semiconductor.

FIG. 14 differs from the embodiment of FIG. 13 in that the gate electrode of the second transistor STR2 and the gate electrode of the fourth transistor STR4 are connected (e.g., electrically connected) to the write scan line GWL, and the gate electrode of the first transistor STR1 is connected (e.g., electrically connected) to the control scan line GCL. In FIG. 14, the first transistor STR1 and the third transistor STR3 may be formed as the N-type MOSFET, so that the scan signal of the gate high voltage may be applied to the control scan line GCL and the initialization scan line GIL. On the other hand, since the second transistor STR2, the fourth transistor STR4, the fifth transistor STR5, and the sixth transistor STR6 are formed as the P-type MOSFET, the scan signal with a gate low voltage may be applied to the write scan line GWL and the light emitting element LE.

It should be noted that the schematic diagram of the equivalent circuit of a pixel according to an embodiment described above is not limited to that shown in FIGS. 12 to 14. The schematic diagram of the equivalent circuit of a pixel according to an embodiment may be formed by other known circuit structures that are employed by those skilled in the art other than the embodiments shown in FIGS. 12 to 14.

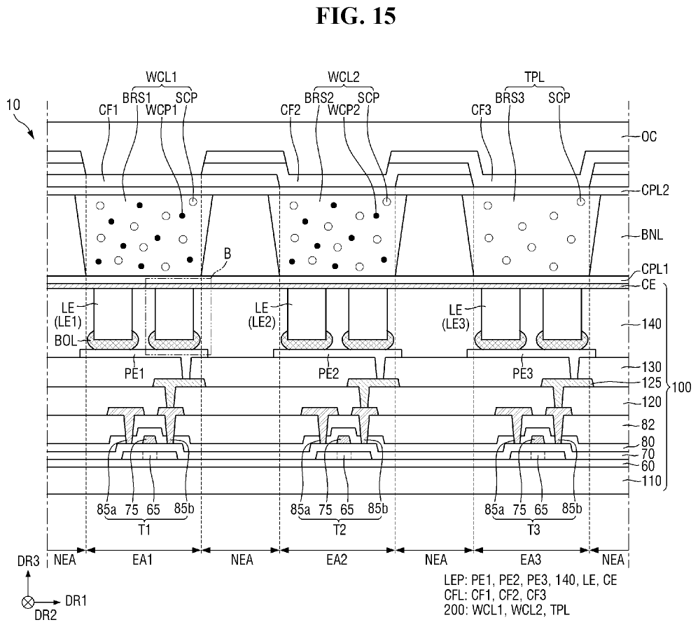

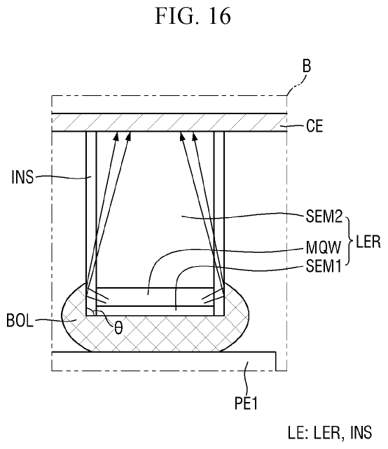

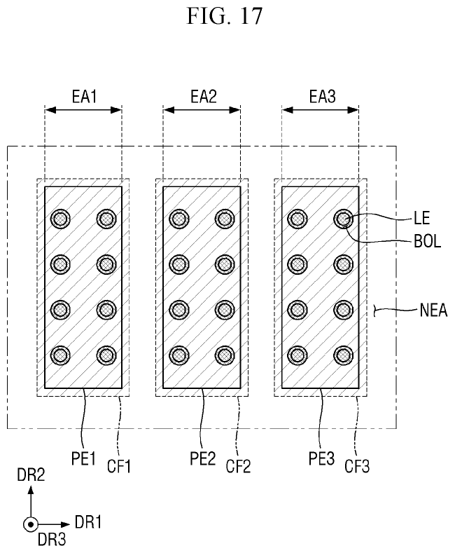

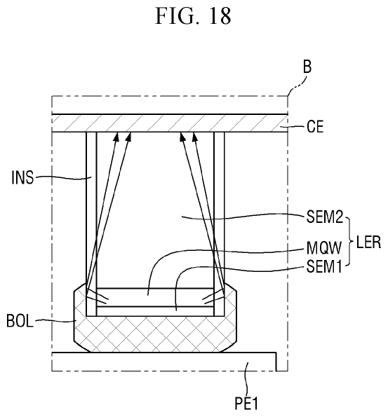

FIG. 15 is a schematic cross-sectional view of a display device according to an embodiment. FIG. 16 is an enlarged schematic view of region B shown in FIG. 15 according to an embodiment. FIG. 17 is a schematic plan view illustrating light emitting regions of a display device. FIG. 18 is an enlarged schematic view of region B shown in FIG. 15 according to another embodiment.

Referring to FIG. 15, the display device 10 may include a display substrate 100, a wavelength control unit 200 and a color filter layer CFL disposed on the display substrate 100.

The display substrate 100 may include a substrate 110 and a light emitting element part LEP disposed on the substrate 110. The substrate 110 may be an insulating substrate. The substrate 110 may include a transparent material. For example, the substrate 110 may include a transparent insulating material such as glass, quartz, or the like. The substrate 110 may be a rigid substrate. However, the substrate 110 is not limited thereto and may include a plastic, such as polyimide, or the like. For example, the substrate 110 may have flexible characteristics to be warped, bent, folded, or rolled. Emitting areas EA1, EA2, and EA3 and non-emitting areas NEA may be defined on the substrate 110.

Switching elements T1, T2, and T3 may be disposed on the substrate 110. In an embodiment, the first switching element T1 may be disposed in the first light emitting area EA1 of the substrate 110, the second switching element T2 may be disposed in the second light emitting area EA2, and the third switching element T3 may be disposed in the third light emitting area EA3. However, embodiments are not limited thereto, and at least one of the first switching element T1, the second switching element T2, and the third switching element T3 may be disposed in the non-emitting area NEA in other embodiments.

In an embodiment, the first switching element T1, the second switching element T2, and the third switching element T3 may each be a thin film transistor including an amorphous silicon, polysilicon, or oxide semiconductor. For example, there may be signal lines (e.g., gate lines, data lines, power supply lines, etc.) further disposed on the substrate 110 that carry signals to each switching element.

Each switching element T1, T2, and T3 may include a semiconductor layer 65, a gate electrode 75, a source electrode 85a, and a drain electrode 85b. For example, a buffer layer 60 may be disposed on the substrate 110. The buffer layer 60 may be disposed to cover a front side of the substrate 110. The buffer layer 60 may include a silicon nitride, a silicon oxide, or a silicon oxynitride, and may be a single layer or a double layer thereof.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, or an oxide semiconductor. In an example, the oxide semiconductor, for example, may include a binary compound (ABₓ), a ternary compound (ABₓC_{y}), or a tetracyclic compound (ABₓC_{y}D_{z}) containing indium, zinc, gallium, tin, titanium, aluminum, hafnium (Hf), zirconium (Zr), magnesium (Mg), and the like. In an embodiment, the semiconductor layer 65 may include indium tin zinc oxide (IGZO).

A gate insulating layer 70 may be disposed on the semiconductor layer 65. The gate insulating layer 70 may include a silicon compound, a metal oxide, or the like. For example, the gate insulating layer 70 may include a silicon oxide, a silicon nitride, a silicon oxynitride, an aluminum oxide, a tantalum oxide, a hafnium oxide, a zirconium oxide, a titanium oxide, and the like. In an embodiment, the gate insulating layer 70 may include a silicon oxide.

The gate electrode 75 may be disposed on the gate insulating layer 70. The gate electrode 75 may overlap the semiconductor layer 65. The gate electrode 75 may include a conductive material. The gate electrode 75 may include a metal oxide such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be formed of a Cu/Ti double layer in which an upper layer of copper is stacked on a lower layer of titanium, but embodiments are not limited thereto.

A first interlayer insulating layer 80 and a second interlayer insulating layer 82 may be disposed on the gate electrode 75. The first interlayer insulating layer 80 may be disposed (e.g., directly disposed) on the gate electrode 75, and the second interlayer insulating layer 82 may be disposed (e.g., directly disposed) on the first interlayer insulating layer 80. The first interlayer insulating layer 80 and the second interlayer insulating layer 82 each may include an inorganic insulating material such as a silicon oxide, a silicon nitride, a silicon oxynitride, a hafnium oxide, an aluminum oxide, a titanium oxide, a tantalum oxide, a zinc oxide, and the like. However, embodiments are not limited thereto, and the second interlayer insulating layer 82 may include an organic insulating material capable of flattening a lower step portion.

The source electrode 85a and a drain electrode 85b may be disposed on the second interlayer insulating layer 82. The source electrode 85a and the drain electrode 85b may be connected (e.g., electrically connected) to the semiconductor layer 65 through contact holes penetrating the first interlayer insulating layer 80, the second interlayer insulating layer 82, and the gate insulating layer 70, respectively. The source electrode 85a and the drain electrode 85b may include metal oxides such as ITO, IZO, ITZO, In₂O₃, or metals such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be formed of a Cu/Ti double layer in which an upper layer of copper is stacked on a lower layer of titanium, but embodiments are not limited thereto.

A first planarization layer 120 may be disposed on the first switching element T1, the second switching element T2, and the third switching element T3. The first planarization layer 120 may include an organic material. For example, the first planarization layer 120 may include an acrylic resin, an epoxy resin, an imide resin, an ester resin, or the like. In an embodiment, the first planarization layer 120 may include a positive photosensitive material or a negative photosensitive material.

A pixel connection electrode 125 may be disposed on the first planarization layer 120. The pixel connection electrode 125 may be disposed to correspond to each of the first switching element T1, the second switching element T2, and the third switching element T3, and may be connected (e.g., electrically connected) to them. The pixel connection electrode 125 may connect pixel electrodes PE1, PE2, and PE3 described later to the switching elements T1, T2, and T3 described above. The pixel connection electrode 125 may contact the switching elements T1, T2, and T3 through a contact hole penetrating the first planarization layer 120.

A second planarization layer 130 may be disposed on the first planarization layer 120 and the pixel connection electrode 125. The second planarization layer 130 may flatten the lower step portion and may include the same material as the first planarization layer 120 described above.

The light emitting element part LEP may be disposed on the second planarization layer 130. The light emitting element part LEP may include pixel electrodes PE1, PE2, and PE3, connection electrodes BOL, light emitting elements LE, and a common electrode CE. For example, the light emitting element part LEP may further include an organic layer 140.

The pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may be connected (e.g., electrically connected) to the light emitting element LE through a connection electrode BOL. The first pixel electrode PE1, the second pixel electrode PE2, and the third pixel electrode PE3 may function as the first electrode of the light emitting element LE and may be an anode electrode or a cathode electrode. The pixel electrodes PE1, PE2, and PE3 may be disposed in the non-emitting area NEA. The pixel electrodes PE1, PE2, and PE3 may not overlap the emitting areas EA1, EA2, and EA3.

Each of the pixel electrodes PE1, PE2, and PE3 may be connected (e.g., directly connected) to the pixel connection electrode 125 through the contact hole penetrating the second planarization layer 130 and may be connected (e.g., electrically connected) to each of the switching elements T1, T2, and T3 through the pixel connection electrode 125. The first pixel electrode PE1, the second pixel electrode PE2, and the third pixel electrode PE3 may include metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. For example, the first pixel electrode PE1, the second pixel electrode PE2, and the third pixel electrode PE3 may have a multilayer structure in which two or more metal layers are stacked. For example, the first pixel electrode PE1, the second pixel electrode PE2, and the third pixel electrode PE3 may have a two-layer structure in which a copper layer is stacked on a titanium layer, but embodiments are not limited thereto.

The light emitting elements LE may be disposed on each of the first pixel electrode PE1, the second pixel electrode PE2, and the third pixel electrode PE3.

Referring to FIG. 16, the light emitting element LE may be disposed such that the first semiconductor layer SEM1 faces the pixel electrode PE1. The connection electrode BOL may be further disposed between the light emitting element LE and the pixel electrode PE1. The connection electrode BOL may function to transmit a light emitting signal from the first pixel electrode PE1 to the light emitting element LE. The connection electrode BOL may be disposed at the lowermost end portion of the light emitting element LE and may be disposed farther from the light emitting layer MQW than the first semiconductor layer SEM1. The connection electrode BOL may include at least one of gold (Au), copper (Cu), tin (Sn), silver (Ag), aluminum (Al), and titanium (Ti). For example, the connection electrode BOL may include a 9:1 alloy of gold and tin, an 8:2 alloy, or a 7:3 alloy, or may include an alloy of copper, silver, and tin (e.g., SAC305).

The connection electrode BOL may surround a side surface of the light emitting element rod LER. For example, the connection electrode BOL may surround the first semiconductor layer SEM1 and the light emitting layer MQW. Accordingly, the light emitted from the light emitting layer MQW may be readily reflected from the connection electrode BOL and emitted upward. As such, the connection electrode BOL surrounding the side surface of the light emitting element rod LER may function as a reflective layer. The thickness of the connection electrode BOL surrounding the side of the light emitting element rod LER may be different according to the height. For example, the connection electrode BOL surrounding the side of the light emitting element rod LER may have the thickest middle portion, but embodiments are not limited thereto. As shown in FIG. 18, the connection electrode BOL surrounding the side of the light emitting element rod LER may be formed to have a constant thickness.

As shown in FIGS. 15 and 16, the light emitting elements LE may be disposed in each of the first light emitting area EA1, the second light emitting area EA2, and the third light emitting area EA3. The light emitting element LE may be the light emitting element LE described with reference to FIGS. 3 to 9.

An angle θ between the side surface of the light emitting element LE and the bottom surface of the first semiconductor layer SEM1 may be greater than or equal to 90 degrees. In case that the side of the light emitting element LE is inclined, light emitted from the light emitting layer MQW may be readily reflected from the connection electrode BOL and emitted upward. Accordingly, light emitting efficiency of the light emitting element LE may be further improved.

The organic layer 140 may be disposed on the pixel electrodes PE1, PE2, and PE3 on which the light emitting element LE is not disposed and the second planarization layer 130. The organic layer 140 may flatten a lower step portion so that the common electrode CE, which will be described later, may be formed. The organic layer 140 may be disposed at the same height as the light emitting elements LE, but embodiments are not limited thereto. For example, the organic layer 140 may be formed to a certain height so that at least a portion of the light emitting elements LE may protrude above the organic layer 140. For example, the height of the organic layer 140 based on the top surface of the first pixel electrode PE1 may be smaller than the height of the light emitting element LE.

The organic layer 140 may include the organic material to planarize the lower step portion. For example, the organic layer 140 may include a polyacrylates resin, an epoxy resin, a phenolic resin, a polyamides resin, or a polyimides rein, unsaturated polyester resin, poly phenylenethers resin, polyphenylenesulfides resin, or benzocyclobutene (BCB).

The common electrode CE may be disposed on the organic layer 140 and the light emitting elements LE. For example, the common electrode CE may be disposed on a surface of the substrate 110 on which the light emitting element LE is formed and may be disposed in the entire display area DPA. The common electrode CE may be disposed to overlap each of the light emitting areas EA1, EA2, and EA3 in the display area DPA, and may have a thin thickness so that light may be emitted.

The common electrode CE may be disposed (e.g., directly disposed) on upper and side surfaces of the light emitting elements LE. For example, the common electrode CE may contact (e.g., directly contact) the second semiconductor layer SEM2 that is the upper surface of the light emitting element LE. The common electrode CE may be a common layer disposed to cover the light emitting elements LE and to connect the light emitting elements LE in common.

Since the common electrode CE is entirely disposed on the substrate 110 and a common voltage is applied, the common electrode CE may include a material having low resistance. For example, the common electrode CE may be formed to have a thin thickness to readily transmit light. For example, the common electrode CE may include a low-resistance metal material such as aluminum (Al), silver (Ag), or copper (Cu) or a metal oxide such as ITO, IZO, or ITZO. The common electrode CE may have a thickness of about 10 Å to about 200 Å, but embodiments are not limited thereto.

The light emitting elements LE may receive a pixel voltage or an anode voltage from each of the pixel electrodes PE1, PE2, and PE3 and may receive a common voltage through the common electrode CE. The light emitting elements LE may emit light having a certain luminance according to a voltage difference between the pixel voltage and the common voltage. In an embodiment, it is possible to eliminate (or prevent) the disadvantages of the organic light emitting diode, which is vulnerable to external moisture or oxygen, and improve the lifespan and reliability by disposing light emitting elements LE, e.g., inorganic light emitting diodes, on the pixel electrodes PE1, PE2, and PE3.

As shown in FIG. 17, the light emitting elements LE may be disposed on each of the pixel electrodes PE1, PE2, and PE3. The light emitting elements LE may be regularly arranged according to a certain rule. For example, the light emitting elements LE may be spaced apart from each other at regular intervals. However, embodiments are not limited thereto, and the light emitting elements LE may be irregularly arranged.

Each of the light emitting elements LE may be substantially disposed on each of the pixel electrodes PE1, PE2, and PE3. However, embodiments are not limited thereto, and some light emitting elements LE may be disposed between each pixel electrode PE1, PE2, and PE3, may be partially disposed across any of the pixel electrodes, or may not be disposed on any pixel electrodes.

For example, a first capping layer CPL1 may be disposed on the substrate 110 on which the common electrode CE is disposed. The first capping layer CPL1 may be disposed (e.g., directly disposed) on the common electrode CE. The first capping layer CPL1 may function to protect components disposed below, e.g., the light emitting elements LE and the common electrode CE, from moisture or debris by covering them.

The first capping layer CPL1 may include an inorganic material. For example, the first capping layer CPL1 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxide. For example, although the drawing illustrates that the first capping layer CPL1 is formed of a single layer, embodiments are not limited thereto. For example, the first capping layer CPL1 may be formed as multiple layers stacked with alternating inorganic layers including at least one of the materials such as materials that the first capping layer CPL1 may include. The thickness of the first capping layer CPL1 may range from about 0.05 μm to about 2 μm, but embodiments are not limited thereto.

For example, the wavelength control unit 200 may be disposed on the light emitting element part LEP. The wavelength control unit 200 may include a first wavelength conversion layer WCL1, a second wavelength conversion layer WCL2, and a light transmitting layer TPL. For example, the wavelength control unit 200 may further include a bank layer BNL.

The bank layer BNL may be disposed on the first capping layer CPL1 and may partition light emitting areas EA1, EA2, and EA3. The bank layer BNL may be disposed to extend in the first and second directions DR1 and DR2 and may be formed in a lattice pattern throughout the display area DPA. For example, the bank layer BNL may not overlap the emitting areas EA1, EA2, and EA3 and may overlap the non-emitting area NEA.

The bank layer BNL may function to provide a space in which the first wavelength conversion layer WCL1, the second wavelength conversion layer WCL2, and the light transmitting layer TPL are formed. For example, the bank layer BNL may have a thickness of about 1 μm to about 10 μm. The bank layer BNL may include an organic insulating material to be formed with a large thickness. The organic insulating material may include, for example, an epoxy-based resin, an acrylic-based resin, a cardo-based resin, or an imide-based resin.

In an embodiment, the bank layer BNL may further include a light blocking material and may include a dye or pigment having light blocking properties. For example, the bank layer BNL may be a black matrix. External light incident from the outside of the display device 10 may cause a problem of distorting the color gamut of the wavelength control unit 200. According to the embodiment, color distortion due to reflection of external light may be reduced by disposing the bank layer BNL including the light blocking material in the wavelength control unit 200. For example, the bank layer BNL including the light blocking material may prevent light from penetrating between adjacent light emitting areas and thus color mixing, thereby further improving color reproducibility.

The first wavelength conversion layer WCL1, the second wavelength conversion layer WCL2, and the light transmitting layer TPL may be disposed on the emitting areas EA1, EA2, and EA3. The first wavelength conversion layer WCL1 and the second wavelength conversion layer WCL2 may convert or shift the peak wavelength of incident light into another specific peak wavelength and emit the light. The first wavelength conversion layer WCL1 may convert blue light emitted from the light emitting element LE into red light, and the second wavelength conversion layer WCL2 may convert blue light into green light. The light transmitting layer TPL may transmit blue light as it is.

The first wavelength conversion layer WCL1, the second wavelength conversion layer WCL2, and the light transmitting layer TPL may be disposed in each of the light emitting areas EA1, EA2, and EA3 partitioned by the bank layer BNL, and may be arranged to be spaced apart from each other. For example, the first wavelength conversion layer WCL1, the second wavelength conversion layer WCL2, and the light transmitting layer TPL may be formed in a dot-shaped island pattern spaced apart from each other.

The first wavelength conversion layer WCL1 may be disposed to overlap the first emitting area EA1. The first wavelength conversion layer WCL1 may convert or shift a peak wavelength of incident light into light having another specific peak wavelength and emit the light. In an embodiment, the first wavelength conversion layer WCL1 may convert blue light emitted from the light emitting element LE of the first light emitting area EA1 into red light having a single peak wavelength in the range of about 610 nm to about 650 nm and may emit the red light.

The first wavelength conversion layer WCL1 may include a first base resin BRS1, first wavelength conversion particles WCP1, and scatterers SCP. The first base resin BRS1 may include a light-transmitting organic material. For example, the first base resin BRS1 may include an epoxy-based resin, an acrylic-based resin, a cardo-based resin, or an imide-based resin.

The first wavelength conversion particle WCP1 may convert blue light incident from the light emitting element LE into red light. For example, the first wavelength conversion particle WCP1 may convert light in a blue wavelength band into light in a red wavelength band. The first wavelength conversion particle WCP1 may be a quantum dot (QD), a quantum rod, a fluorescent material, or a phosphorescent material. For example, the quantum dot may be a certain material that emits a specific color while electrons transition from a conduction band to a valence band.

The quantum dots may be semiconductor nanocrystalline materials. According to its composition and size, the quantum dot may have a specific bandgap to absorb light and emit light having a unique wavelength. Examples of the semiconductor nanocrystals of the quantum dots include IV group nanocrystals, II-VI group compound nanocrystals, III-V group compound nanocrystals, IV-VI group nanocrystals, or combinations thereof.

The group II-VI compound may be a binary compound selected from the group consisting of CdSe, CdTe, ZnS, ZnSe, ZnTe, ZnO, HgS, HgSe, HgTe, MgSc, MgS, and mixtures thereof; InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and ternary compounds selected from the group consisting of mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound may be a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GalnNAs, GalnNSb, GalnPAs, GalnPSb, InAlNP, InAlNAs, InAlNSb, InAlPAs, InAlPSb, and mixtures thereof.

The group IV-VI compounds may be selected from the group consisting of binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In an embodiment, the quantum dot may have a core-shell structure including a core including a nanocrystal as described above and a shell surrounding the core. The shell of the quantum dot may function as a protective layer to prevent chemical denaturation of the core to maintain semiconductor properties and/or as a charging layer to impart electrophoretic properties to the quantum dot. The shell may be a monolayer or a multilayer. Examples of shells for the quantum dots include oxides of metals or non-metals, semiconductor compounds, or combinations thereof.

For example, the oxides of said metals or non-metals may include binary compounds such as SiO₂, Al₂O₃, TiO₂, ZnO, MnO, Mn₂O₃, Mn₃O₄, CuO, FeO, Fe₂O₃, Fc₃O₄, CoO, Co₃O₄, NiO, or ternary compounds such as MgAl₂O₄, CoFc₂O₄, NiFc₂O₄, CoMn₂O₄, but embodiments are not limited thereto.

For example, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc but embodiments are not limited thereto.

The scatterer SCP may scatter the light of the light emitting element LE in a random direction. The scatterer SCP may have a refractive index different from that of the first base resin BRS1 and form an optical interface with the first base resin BRS1. For example, the scatterer SCP may be a light scattering particle. The scatterer SCP is not limited to any material capable of scattering at least a portion of the transmitted light, but may be, for example, metal oxide particles or organic particles. Examples of the metal oxide include titanium oxide (TiO₂), zirconium oxide (ZrO₂), aluminum oxide (Al₂O₃), indium oxide (In₂O₃), zinc oxide (ZnO), tin oxide (SnO₂), and the like, and examples of organic particle materials include acrylic resins or urethane resins. The scatterer SCP may scatter light in the random direction regardless of the incident direction of incident light without substantially converting the wavelength of light.

The second wavelength conversion layer WCL2 may be disposed to overlap the second emission area EA2. The second wavelength conversion layer WCL2 may convert or shift the peak wavelength of incident light into light having another specific peak wavelength and emit the light. In an embodiment, the second wavelength conversion layer WCL2 may convert blue light emitted from the light emitting element LE of the second light emitting area EA2 into green light having the peak wavelength in a range of about 510 nm to about 550 nm and emit it.

The second wavelength conversion layer WCL2 may include a second base resin BRS2 and second wavelength conversion particles WCP2 and scatterers SCP dispersed in the second base resin BRS2.

The second base resin BRS2 may be made of a material having high light transmittance and may be made of the same material as the first base resin BRS1 or may include at least one of the materials as constituent materials thereof.

The second wavelength conversion particle WCP2 may convert or shift the peak wavelength of incident light to another specific peak wavelength. In an embodiment, the second wavelength conversion particle WCP2 may convert blue light provided from the light emitting element LE into green light having a peak wavelength in a range of about 510 nm to about 550 nm and emit it. Examples of the second wavelength conversion particle WCP2 include quantum dots, quantum rods, or phosphors. A more specific description of the second wavelength conversion particle WCP2 is substantially the same as or similar to that described above in the description of the first wavelength conversion particle WCP1, and thus will be omitted for descriptive convenience.

The light transmitting layer TPL may be disposed to overlap the third light emitting area EA3. The light transmitting layer TPL may transmit incident light. The light transmitting layer TPL may transmit blue light emitted from the light emitting element LE disposed in the third light emitting area EA3 as it is. The light transmitting layer TPL may include a third base resin BRS3, and scatterers SCP dispersed in the third base resin BRS3. Since the third base resin BRS3 is substantially the same as or similar to the first base resin BRS3 described above, a description thereof will be omitted for descriptive convenience.

The light transmitted to the wavelength control unit 200 may implement (or display) full color by passing through the color filter layer CFL, which will be described later.

The wavelength control unit 200 may further include a second capping layer CPL2. The second capping layer CPL2 may cover the first wavelength conversion layer WCL1, the second wavelength conversion layer WCL2, the light transmitting layer TPL, and the bank layer BNL disposed thereunder to protect them from moisture or foreign matter. The second capping layer CPL2 may include an inorganic material and may include a material substantially the same as or similar to that of the first capping layer CPL1 described above.

A first color filter CF1, a second color filter CF2, and a third color filter CF3 may be disposed on the second capping layer CPL2. The first color filter CF1 may be disposed in the first light emitting area EA1, the second color filter CF2 may be disposed in the second light emitting area EA2, and the third color filter CF3 may be disposed in the third light emitting area EA3.

The first color filter CF1, the second color filter CF2, and the third color filter CF3 may include colorants such as dyes or pigments that absorb wavelengths other than the corresponding color wavelengths. The first color filter CF1 may selectively transmit red light and block or absorb blue light and green light. The second color filter CF2 may selectively transmit green light and block or absorb blue light and red light. The third color filter CF3 may selectively transmit blue light and block or absorb red light and green light. For example, the first color filter CF1 may be a red color filter, the second color filter CF2 may be a green color filter, and the third color filter CF3 may be a blue color filter.

In an embodiment, light incident on the first color filter CF1 may be light converted into red light by the first wavelength conversion layer WCL1, and light incident on the second color filter CF2 may be light converted into green light by the second wavelength conversion layer WCL2, and light incident on the third color filter CF3 may be blue light transmitted through the light transmitting layer TPL. Thus, the red light transmitted through the first color filter CF1, the green light transmitted through the second color filter CF2, and the blue light transmitted through the third color filter CF3 may be emitted onto the upper of the substrate 110 to achieve (or display) full color.

The first color filter CF1, the second color filter CF2, and the third color filter CF3 may absorb some of the light introduced from the outside of the display device 10 to reduce reflected light caused by external light. Accordingly, the first color filter CF1, the second color filter CF2, and the third color filter CF3 may prevent color distortion due to external light reflection.

As shown in FIG. 17, the plane area of each of the first color filter CF1, the second color filter CF2, and the third color filter CF3 may be greater than the plane area of each of the light emitting areas EA1, EA2, and EA3. For example, the first color filter CF1 may have a larger plane area than the first emitting area EA1. The second color filter CF2 may have a larger plane area than the second light emitting area EA2. The third color filter CF3 may have a larger plane area than the third light emitting area EA3. However, embodiments are not limited thereto, and the plane area of each of the first color filter CF1, the second color filter CF2, and the third color filter CF3 may be substantially equal to the plane area of each of the light emitting areas EA1, EA2, and EA3.

For example, the first color filter CF1 may be disposed in the non-emitting area NEA, and at least one of the second color filter CF2 and the third color filter CF3 may be further disposed to overlap each other. For example, the first color filter CF1, the second color filter CF2, and the third color filter CF3 may be disposed in the non-emitting area NEA.

Accordingly, light emission from the display device may be blocked in the non-emitting area NEA, and reflection of external light may be suppressed. Each color filter CF1, CF2, and CF3 may block the emission of light of a color other than the corresponding color of each light emitting area EA1, EA2, and EA3, and accordingly, light of red, green, and blue colors may all be blocked in the non-emitting area NEA. However, embodiments are not limited thereto, and a light absorbing member including a light absorbing material, which absorbs a visible light wavelength band, may be disposed in the non-emitting area NEA.

An overcoat layer OC may be disposed on the color filter layer CFL. The overcoat layer OC may be disposed (e.g., directly disposed) on the color filter layer CFL. The overcoat layer OC may be disposed (e.g., entirely disposed) in the display area DPA and may have a flat surface. The overcoat layer OC may flatten a step portion formed by the lower color filter layer CFL. The overcoat layer OC may include the light-transmitting organic material.

In another example, the first light emitting element LE1 disposed in the first light emitting area EA1 may emit a first light of blue color, the second light emitting element LE2 disposed in the second light emitting area EA2 may emit a second light of red color, and the third light emitting element LE3 disposed in the third light emitting area LE3 may emit a third light of green color. In case that the light emitting elements disposed in different light emitting areas may emit light of different wavelengths, the wavelength control unit 200 and the color filter layer CFL described with reference to FIG. 15 may be omitted for descriptive convenience.

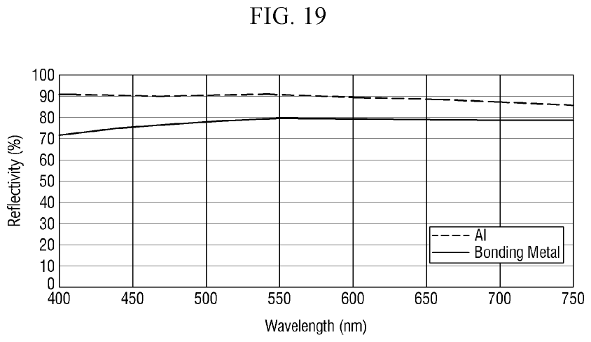

FIG. 19 is a graph to illustrate the reflectivity of a connection electrode according to an embodiment.

In FIG. 19, the dotted line represents a reflectance according to the wavelength in case that an aluminum reflective layer is formed on the side surface of a conventional light emitting element, and the solid line represents the reflectance according to the wavelength in case that the connection electrode of the light emitting element is formed to surround the light emitting layer according to an embodiment. As shown in FIG. 19, in case that the connection electrode of the light emitting element is formed to surround the light emitting layer according to an embodiment, the light emitting element may have a reflectance of 70% or more at all wavelengths without a separate reflective layer.

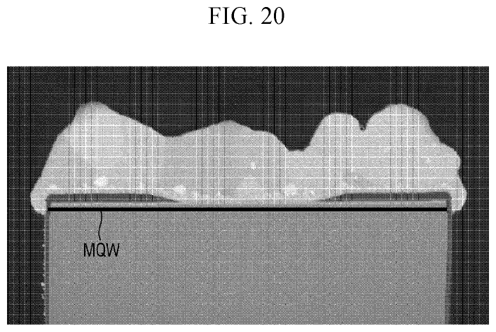

FIG. 20 is a SEM picture taken with a scanning electron microscope of a light emitting element according to an embodiment.

Referring to FIG. 20, the connection electrode may be formed to surround the side surface of the light emitting layer MQW of the light emitting element. Accordingly, light emitted from the light emitting layer MQW may be reflected by the connection electrode BOL and emitted upward, so that the light emitting efficiency may be increased.

Hereinafter, a manufacturing process of the display device 10 according to an embodiment will be described with reference to other drawings.

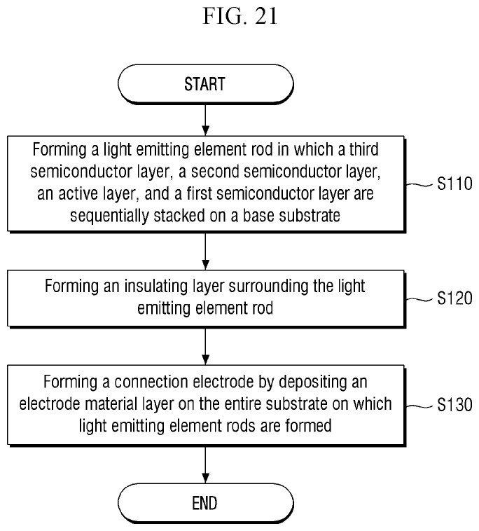

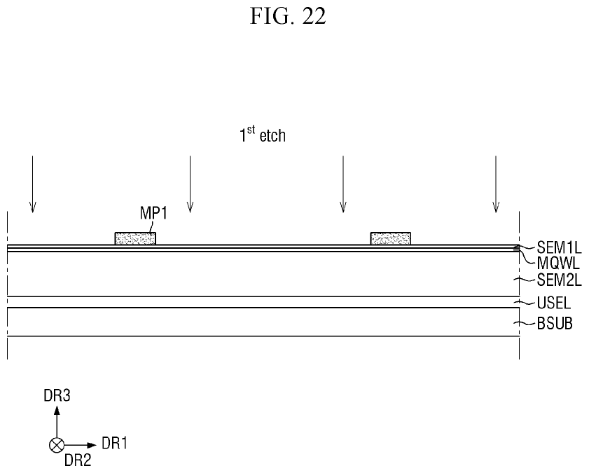

FIG. 21 is a flowchart to illustrate steps of a method of manufacturing the display device according to an embodiment. FIGS. 22 to 29 are diagrams to illustrate the steps of FIG. 21. FIGS. 22 to 29 are schematic cross-sectional views of structures according to the formation order of each layer of the display device 10.

FIGS. 21 to 29 illustrate manufacturing processes of the light emitting element part LEP, and these may correspond to the schematic cross-sectional view of FIG. 7. In the following, the first light emitting area EA1 and the second light emitting area EA2 of the display device 10 are illustrated. For example, for convenience of description, a single light emitting element LE may be disposed in a single light emitting area EA1, but embodiments are not limited thereto.

Referring to FIG. 21, the method of manufacturing a display device 10 may include forming a light emitting element rod LER in which a third semiconductor layer USE, a second semiconductor layer SEM2, a light emitting layer MQW, and a first semiconductor layer SEM1 are sequentially stacked on a base substrate BSUB (step S110), forming an insulating layer INS surrounding the light emitting element rod LER (step S120), and forming a connection electrode BOL by depositing an electrode material layer on the entire substrate on which light emitting element rods LER are formed (step S130).

A detailed example of the steps in FIG. 21 will be described below with reference to FIGS. 22 to 29.

Referring to FIGS. 22 to 25, light emitting elements LE may be formed on a base substrate BSUB.

For example, referring to FIG. 22, the base substrate BSUB may be prepared. The base substrate BSUB may be a sapphire substrate Al₂O₃ or a silicon wafer including silicon. However, embodiments are not limited thereto, and in an embodiment, a case where the base substrate BSUB is a sapphire substrate will be described as an example.

Semiconductor material layers USEL, SEM2L, MQWL, and SEM1L may be formed on the base substrate BSUB. The semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and the like, and formed by metal organic chemical vapor deposition (MOCVD). However, embodiments are not limited thereto.

A precursor material for forming the semiconductor material layers is not limited within the range that is conventionally selected for forming the subject material. In an example, the precursor material may be a metal precursor including an alkyl group such as a methyl or ethyl group. For example, the precursor material may be a compound such as trimethyl gallium (Ga(CH₃)₃), trimethyl aluminum (Al(CH₃)₃), triethyl phosphate ((C₂H₅)₃PO₄) but embodiments are not limited thereto.

For example, a third semiconductor material layer USEL may be formed on the base substrate BSUB. While the drawings illustrate the third semiconductor material layer USEL being further stacked, embodiments are not limited thereto, and a plurality of layers may be formed. The third semiconductor material layer USEL may be disposed to reduce a lattice constant difference between a second semiconductor material layer SEM2L and the base substrate BSUB. For example, the third semiconductor material layer USEL may include an undoped semiconductor, which is an n-type or p-type undoped material. In an embodiment, the third semiconductor material layer USEL may be at least one of undoped InAlGaN, GaN, AlGaN, InGaN, AlN, and InN, but embodiments are not limited thereto.

The second semiconductor material layer SEM2L, the light emitting material layer MQWL, and the first semiconductor material layer SEM1L may be sequentially formed on the third semiconductor material layer USEL by using the above-described method.

Then, the light emitting element rods LER may be formed by etching the semiconductor material layers USEL, SEM2L, MQWL, and SEM1L.

For example, first mask patterns MP1 may be formed on the first semiconductor material layer SEM1L. The first mask pattern MP1 may be a hard mask including an inorganic material or a photoresist mask including an organic material. The first mask pattern MP1 may prevent semiconductor material layers USEL, SEM2L, MQWL, and SEM1L, which are under the first mask pattern MP1, from being etched. Then, a portion of the semiconductor material layers may be etched (e.g., 1st etch) using the first mask patterns MP1 as a mask to form the light emitting element rods LER.

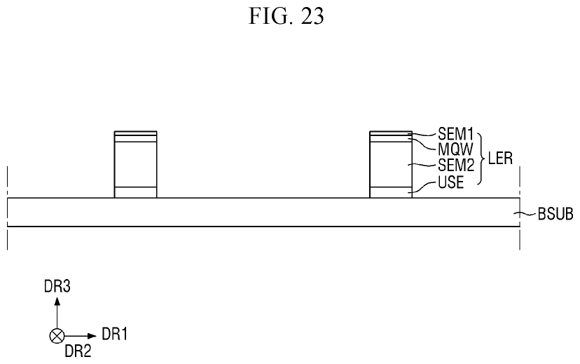

As shown in FIG. 23, on the base substrate BSUB, the semiconductor material layers USEL, SEM2L, MQWL, and SEM1L, which non-overlap the first mask pattern MP1, may be etched and removed, and the portions, which are not etched and overlap the first mask pattern MP1, may be formed into the light emitting element rods LER.

The semiconductor material layers USEL, SEM2L, MQWL, and SEM1L may be etched by conventional methods. For example, the process of etching the semiconductor material layers USEL, SEM2L, MQWL, and SEM1L may be a dry etching process, a wet etching process, a reactive ion etching (RIE) process, a deep reactive ion etching (DRIE) process, an inductively coupled plasma reactive ion etching (ICP-RIE) process, and the like. In the case of dry etching methods, an anisotropic etching process may be suitable for vertical etching. In case of utilizing the etching method described above, the etchant may be Cl₂ or O₂. However, embodiments are not limited thereto.

The semiconductor material layers USEL, SEM2L, MQWL, and SEM1L overlapping the first mask pattern MP1 may not be etched, but may be formed into the light emitting elements LE. Thus, the light emitting element rods LER may be formed including the third semiconductor layer USE, the second semiconductor layer SEM2, the light emitting layer MQW, and the first semiconductor layer SEM1.

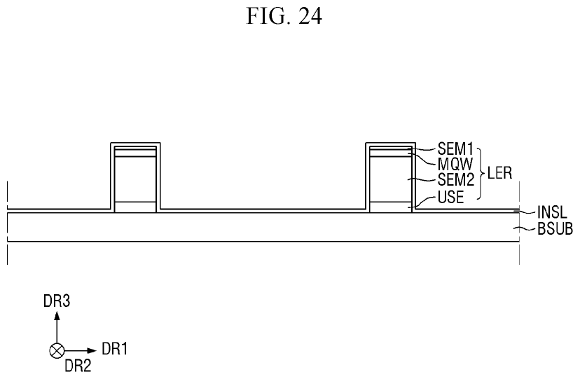

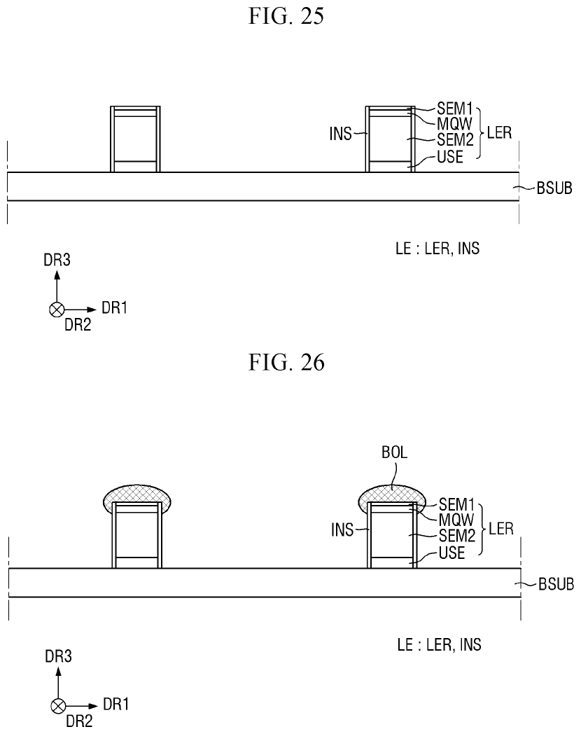

Referring to FIGS. 24 and 25, the insulating layer INS may be formed on the base substrate BSUB on which the light emitting element rods LER are formed.

For example, the insulating material layer INSL may be formed on the outer surfaces of the light emitting element rods LER. The insulating material layer INSL may be formed on the entire surface of the base substrate BSUB and may be formed not only on the light emitting element rods LER, but also on the upper surface of the base substrate BSUB exposed by the light emitting element LE.

Then, a second etch (e.g., 2nd etch) may be performed to partially remove the insulating material layer INSL to form the light emitting element LE including the insulating layer INS.

For example, the second etching process may be performed to partially remove a portion of the insulating material layer INSL such that the insulating material layer INSL may expose the upper surface of the light emitting element rod LER, but may surround the sides of the light emitting element LE. For example, a portion of the insulating material layer INSL may be removed to expose the upper surface of the first semiconductor layer SEM1 of the light emitting element LE in this process. The process of partially removing the insulating material layer INSL may be performed by a process such as anisotropic dry etching or etch-back.

Next, referring to FIG. 26, the connection electrode BOL may be formed on the light emitting element LE to cover a side (or end portion) of the light emitting element rod LER by using an electron beam evaporation method.

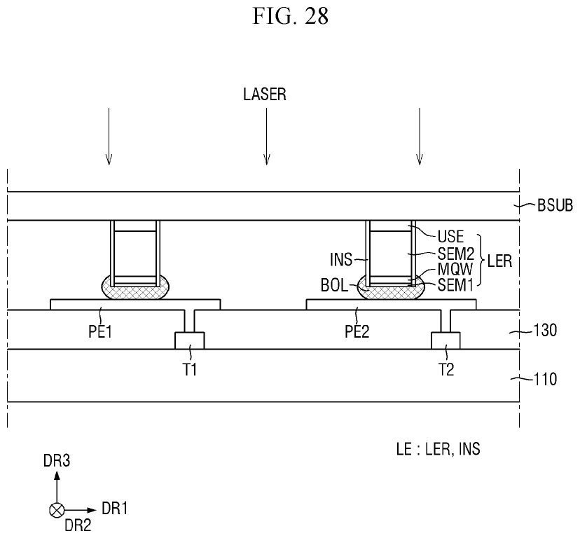

The electron beam evaporation method may be a vacuum deposition method using a high voltage between ionized vaporized metals and may be a method using electrons instead of heat. As described above, according to an embodiment, the connection electrode BOL may be formed on the light emitting element LE without a mask. Therefore, the diameter (or size/width) of the connection electrode may be formed larger than the diameter (or size/width) of the light emitting element. Thus, stitch unevenness may be improved by forming the connection electrode having a larger diameter than the diameter of the light emitting element. By forming the connection electrode having a larger diameter than the diameter of the light emitting element, it is possible to eliminate (or prevent) alignment deviation of the light emitting element to the substrate. Thus, tilting of the light emitting element may be prevented in case of bonding the light emitting element onto the substrate. As such, since the mask process is eliminated (or omitted), process cost and time may be reduced. However, in case that the connection electrode BOL is formed on an end portion of the light emitting element rod LER by using the electron beam evaporation method, the material forming the connection electrode BOL may also be deposited on a first side of the base substrate BSUB on which the light emitting element LE is not disposed. However, the material forming the connection electrode BOL that is deposited on the first side of the base substrate BSUB may be removed together with the material deposited on the base substrate BSUB in case that the base substrate BSUB is separated from the light emitting element LE, as described later with reference to FIG. 28.

In another example, any one of sputtering and molecular beam epitaxy (MBE) may be used in addition to the electron beam evaporation method.

In another example, as described with reference to FIGS. 7 to 9, at least one of the upper and side surfaces of the deposition surface may be formed to be flat by adding an etching step.

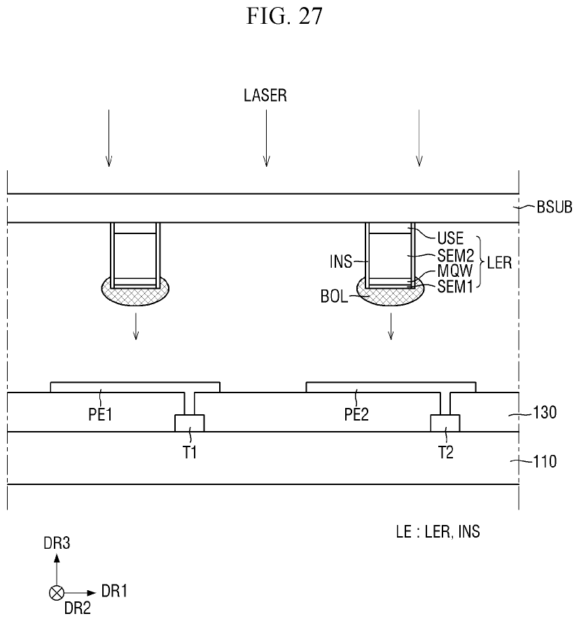

Next, referring to FIGS. 27 and 28, the light emitting element LE having the connection electrode BOL may be attached to the first and second pixel electrodes PEL and PE2.

For example, the substrate 110 having the first and second switching elements T1 and T2 and the first and second pixel electrodes PEL and PE2 may be prepared.

The substrate 110 may be an insulating substrate. The substrate 110 may include a transparent material. For example, the substrate 110 may include a transparent insulating material such as glass or quartz or the like. The substrate 110 may be a rigid substrate. However, the substrate 110 is not limited thereto and may include plastic such as polyimide, or the like, and may have flexible properties to be warped, bent, folded, or rolled.

In an embodiment, each of the first and second switching elements T1 and T2 may be a thin film transistor including amorphous silicon, polysilicon, or an oxide semiconductor. For example, signal lines (e.g., gate lines, data lines, power supply lines, etc.) for transmitting signals to the first and second switching elements T1 and T2 may be further disposed on the substrate 110.

Each of the first and second switching elements T1 and T2 may include a semiconductor layer, a gate electrode, a source electrode, and a drain electrode. For example, the semiconductor layer may form a channel of each of the switching elements T1, T2, and T3. The semiconductor layer may include amorphous silicon, polycrystalline silicon, or an oxide semiconductor. The gate electrode may include a conductive material. The gate electrode may include a metal oxide such as ITO, IZO, ITZO, or In₂O₃, or a metal such as copper (Cu), titanium (Ti), aluminum (Al), molybdenum (Mo), tantalum (Ta), calcium (Ca), chromium (Cr), magnesium (Mg), or nickel (Ni). The source electrode and the drain electrode may be in contact with the semiconductor layer, and may include metal oxides such as ITO, IZO, ITZO, In₂O₃, or metals such as copper (Cu), titanium (Ti), aluminum (Al), molybdenum (Mo), tantalum (Ta), calcium (Ca), chromium (Cr), magnesium (Mg), and nickel (Ni).

The second planarization layer 130 may be disposed on each of the first and second switching elements T1 and T2. The second planarization layer 130 may include an organic material. For example, the second planarization layer 130 may include an acrylic-based resin, an epoxy-based resin, an imide-based resin, an ester-based resin, or the like. In an embodiment, the second planarization layer 130 may include a positive photosensitive material or a negative photosensitive material.

The pixel electrodes PEL and PE2 may be disposed on the second planarization layer 130. The pixel electrodes PEL and PE2 may be disposed to correspond to each of the first and second switching elements T1 and T2 and may be connected (e.g., electrically connected) to them. The pixel electrodes PEL and PE2 may contact the first and second switching elements T1 and T2 through contact holes penetrating the second planarization layer 130.

Next, the base substrate BSUB may be aligned on the substrate 110. At this time, the connection electrode BOL of the light emitting element LE may be aligned on the pixel electrodes PEL and PE2 formed on the base substrate BSUB to face the substrate 110.

Subsequently, the substrate 110 and the base substrate BSUB may be bonded together. For example, the connection electrode BOL of the light emitting element LE formed on the base substrate BSUB may be transferred into contact with the pixel electrodes PEL and PE2 of the substrate 110. At this time, the connection electrode BOL of the light emitting element LE may be in contact with the pixel electrodes PEL and PE2. For example, the substrate 110 and the base substrate BSUB may be bonded by melting and bonding the connection electrode BOL of the light emitting element LE and the pixel electrodes PEL and PE2. The light emitting elements LE may be bonded to the upper surfaces of the pixel electrodes PEL and PE2.

The melting bonding may be performed by irradiating a laser onto the pixel electrodes PE1 and PE2 on the base substrate BSUB. The laser-irradiated pixel electrodes PEL and PE2 may conduct high heat from the laser to bond the interface of the connection electrode BOL of the light emitting element LE and the pixel electrodes PEL and PE2. For example, the pixel electrodes PEL and PE2 may include copper (Cu) having excellent heat conduction and may have excellent adhesive properties with the connection electrode BOL of the light emitting element LE. The source of the laser used for the fusion bonding may be a YAG laser.

For example, the light emitting elements LE may be separated from the base substrate BSUB by irradiating the laser LASER to the base substrate BSUB. The base substrate BSUB may be separated from each third semiconductor layer USE of the light emitting elements LE.

The process of separating the base substrate BSUB may be separated by a laser lift off (LLO) process. The laser lift-off process may use a laser, and a KrF excimer laser (having about 248 nm wavelength) may be used as a source. The energy density of the excimer laser may be irradiated in the range of about 550 mJ/cm² to about 950 mJ/cm², and the incident area may be in the range of about 50×50 μm² to about 1×1 cm², but embodiments are not limited thereto. As the laser is irradiated to the base substrate BSUB, the base substrate BSUB may be separated from the light emitting element LE.

Thereafter, the third semiconductor layer USE may be non-conductive and may be removed for connection of the common electrode CE. The third semiconductor layer USE may be removed by an ashing process. Some of the third semiconductor layer USE may remain behind.

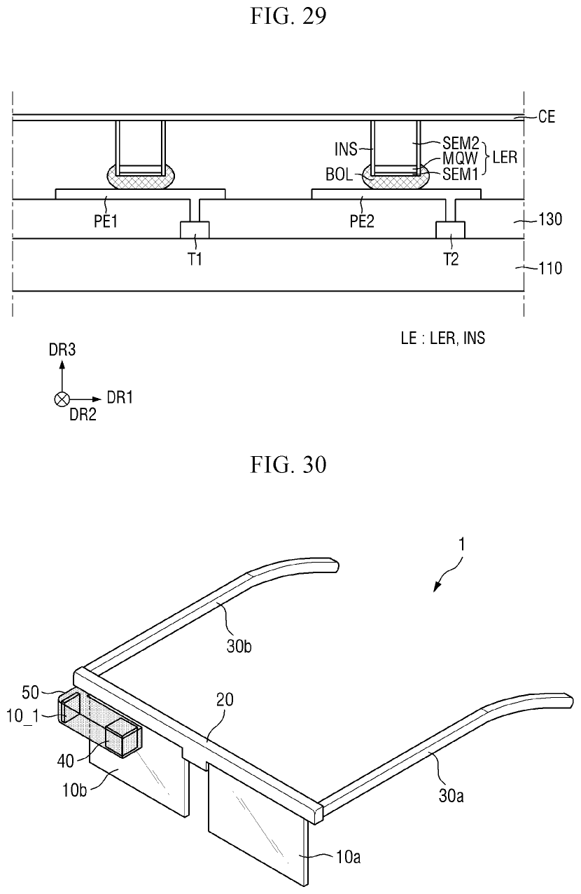

Referring to FIG. 29, the organic layer 140 and the common electrode CE may be formed.

For example, the organic layer 140 may be formed on the second planarization layer 130 and the pixel electrodes PEL and PE2 on which the light emitting element LE is not disposed.

The common electrode CE may be formed on the light emitting element LE and the organic layer 140. The common electrode CE may be continuously formed over the entire display area. The common electrode CE may cover the organic layer 140 and the light emitting element LE, and may contact (e.g., directly contact) them. The common electrode CE may be formed in direct contact with the upper surface of the second semiconductor layer SEM2 of the light emitting element LE.

Then, as shown in FIG. 15, the display device 10 according to an embodiment may be manufactured by forming a partition wall unit, a wavelength control layer, a color filter layer, and the like.

Although the disclosure describes that the light emitting element formed on the base substrate BSUB is bonded to the substrate 110, it may be stretched using a stretched substrate.

The stretchable substrate may include a stretchable material. The stretchable material may include, for example, polyolefine, polyvinyl chloride (PVC), elastomeric silicone, elastomeric polyurethane, elastomeric polyisoprene, and the like. By transferring the light emitting elements LE onto such the stretchable substrate and then stretching it, the space between the light emitting elements LE may be adjusted.

FIG. 30 is an example diagram illustrating a virtual reality device including a display device according to an embodiment. FIG. 30 illustrates a virtual reality device 1 in which the display device 10 according to an embodiment is used.

Referring to FIG. 30, the virtual reality device 1 according to an embodiment may be a device, which is formed as glasses. The virtual reality device 1 according to an embodiment may include a display device 10_1, a left-eye lens 10a, a right-eye lens 10b, a support frame 20, left and right legs 30a and 30b, a reflective member 40, and a display device housing 50.

FIG. 30 illustrates the virtual reality device 1 including the two legs 30a and 30b. However, embodiments are not limited thereto. The virtual reality device 1 according to an embodiment may be used in a head-mounted display including a head-mounted band that is mounted on a head instead of the legs 30a and 30b. For example, the virtual reality device 1 according to an embodiment may not be limited to the example shown in FIG. 30, and may be applied in various forms and in various electronic devices.

The display device housing 50 may receive the display device 10_1 and the reflective member 40. An image displayed on the display device 10_1 may be reflected from the reflective member 40 and provided to a user's right eye through the right-eye lens 10b. Thus, the user may view a virtual reality image displayed on the display device 10_1 via the right eye.

FIG. 30 illustrates that the display device housing 50 is disposed at a right end portion of the support frame 20. However, embodiments are not limited thereto. For example, the display device housing 50 may be disposed at a left end portion of the support frame 20. For example, the image displayed on the display device 10_1 may be reflected from the reflective member 40 and provided to the user's left eye via the left-eye lens 10a. Thus, the user may view the virtual reality image displayed on the display device 10_1 via the left eye. As another example, the display device housing 50 may be disposed at each of the left end portion and the right end portion of the support frame 20. For example, the user may view the virtual reality image displayed on the display device 10_1 via both the left eye and the right eye.

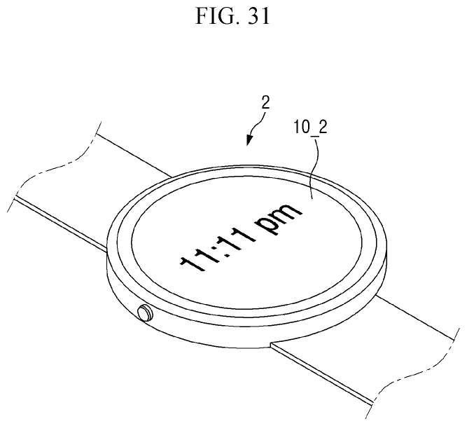

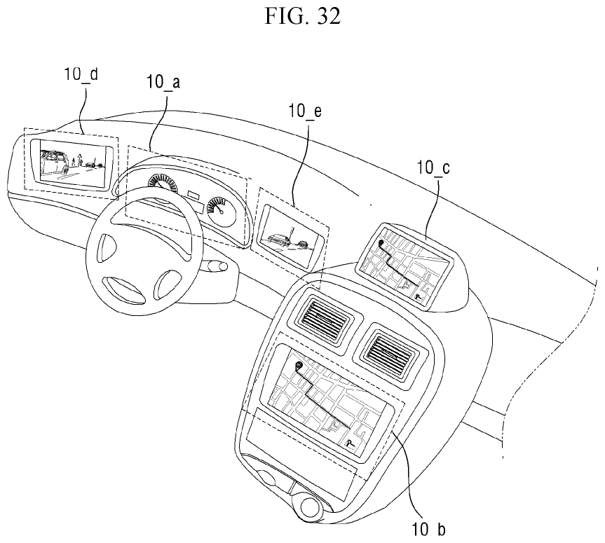

FIG. 31 is an example diagram illustrating a smart device including a display device according to an embodiment.

Referring to FIG. 31, a display device 10_2 according to an embodiment may be applied to a smart watch 2 as one of smart devices.

FIG. 32 is an example diagram illustrating a vehicle including a display device according to an embodiment. FIG. 32 illustrates a vehicle in which display devices according to an embodiment are used.

Referring to FIG. 32, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to each room mirror display that replaces each of side-view mirrors of the vehicle.

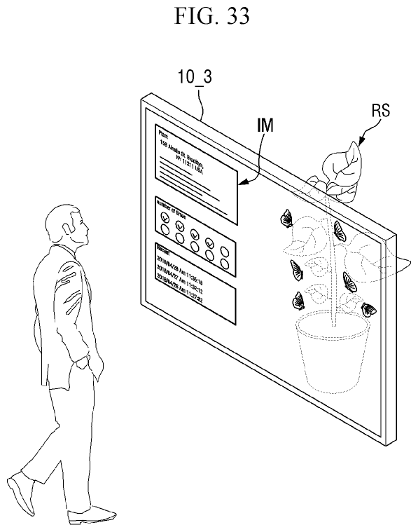

FIG. 33 is an example diagram illustrating a transparent display device including a display device according to an embodiment.

Referring to FIG. 33, a display device according to an embodiment may be applied to a transparent display device. The transparent display device may transmit light therethrough and may display an image IM thereon. Therefore, a user located in front of the transparent display device may not only view the image IM displayed on the display device 10_3, but also view an object RS or a background located in rear of the transparent display device. In case that the display device 10 is applied to the transparent display device, the substrate 110 of the display device 10 shown in FIG. 7 may include a light transmitting portion that transmits light therethrough or is made of a material that transmits light therethrough.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A light emitting element array comprising:
a base substrate;
a plurality of light emitting elements, each of the plurality of light emitting elements including:
a light emitting element rod including a third semiconductor layer, a second semiconductor layer, a light emitting layer, and a first semiconductor layer sequentially stacked on the base substrate; and
an insulating layer surrounding the light emitting element rod; and
a connection electrode disposed on the first semiconductor layer of each of the plurality of light emitting elements, wherein
a diameter of the connection electrode is greater than a diameter of the light emitting element, and
the connection electrode surrounds a side surface of the first semiconductor layer and a side surface of the light emitting layer.

2. The light emitting element array of claim 1, wherein
the connection electrode includes:
a first portion disposed on the first semiconductor layer, and
a second portion disposed on a side surface of the light emitting element rod, and
the first portion of the connection electrode is convex upward.

3. The light emitting element array of claim 2, wherein a diameter of the second portion of the connection electrode is changed according to a height of the second portion.

4. The light emitting element array of claim 2, wherein a diameter of the second portion of the connection electrode is substantially constant according to a height of the second portion.

5. The light emitting element array of claim 1, wherein
the connection electrode includes:
a first portion disposed on the first semiconductor layer, and
a second portion disposed on a side surface of the light emitting element rod,
the first portion of the connection electrode has a flat upper surface, and
a diameter of the second portion of the connection electrode is changed according to a height of the second portion.

6. The light emitting element array of claim 1, wherein
the connection electrode includes:
a first portion disposed on the first semiconductor layer, and
a second portion disposed on a side surface of the light emitting element rod,
the first portion of the connection electrode has a flat upper surface, and
a width of the second portion of the connection electrode is substantially constant according to a height of the second portion.

7. The light emitting element array of claim 1, wherein each of the plurality of light emitting elements has at least one of a circular shape, a hexagonal shape, and a rectangular shape in a plan view.

8. A display device comprising:
a substrate including a pixel electrode;
a plurality of light emitting elements, each of the plurality of light emitting elements including:
a light emitting element rod including a first semiconductor layer, a light emitting layer, and a second semiconductor layer sequentially stacked on the pixel electrode of the substrate, and
an insulating layer surrounding the light emitting element rod;
a connection electrode disposed between the pixel electrode and the plurality of light emitting elements; and
a common electrode disposed on the light emitting element, wherein
a diameter of the connection electrode is greater than a diameter of the light emitting element, and
the connection electrode surrounds a side surface of the first semiconductor layer and a side surface of the light emitting layer.

9. The display device of claim 8, wherein
the connection electrode includes:
a first portion disposed on the first semiconductor layer, and
a second portion disposed on a side surface of the light emitting element rod, and
a diameter of the second portion of the connection electrode is changed according to a height of the second portion.

10. The display device of claim 8, wherein
the connection electrode includes:
a first portion disposed on the first semiconductor layer, and
a second portion disposed on a side surface of the light emitting element rod, and
a diameter of the second portion is substantially constant according to a height of the second portion.

11. The display device of claim 8, wherein each of the plurality of light emitting elements has at least one of a circular shape, a hexagonal shape, and a rectangular shape in a plan view.

12. The display device of claim 8, wherein the connection electrode includes at least one of gold (Au), copper (Cu), tin (Sn), silver (Ag), aluminum (Al), and titanium (Ti).

13. A method of manufacturing a light emitting element comprising:
forming a light emitting element rod including a third semiconductor layer, a second semiconductor layer, a light emitting layer, and a first semiconductor layer sequentially stacked on a base substrate;
forming an insulating layer surrounding the light emitting element rod; and
forming a connection electrode having a diameter larger than a diameter of the light emitting element and surrounding a portion of a side surface of the light emitting element rod on a substrate on which the light emitting element rod is formed.

14. The method of claim 13, wherein the forming of the connection electrode is performed by at least one of an electron beam evaporation method, a sputtering method, and a molecular beam epitaxy (MBE) method.

15. The method of claim 14, wherein the connection electrode surrounds a side surface of the first semiconductor layer and a side surface of a light emitting layer.

16. The method of claim 14, further comprising:
aligning the light emitting element on which the connection electrode is formed on a substrate on which a pixel electrode is formed;
bonding the connection electrode to the pixel electrode;
removing the base substrate and the third semiconductor layer; and
forming a common electrode on the light emitting element.

17. The method of claim 15, wherein
the connection electrode includes:
a first portion disposed on the first semiconductor layer, and
a second portion disposed on a side surface of the light emitting element rod, and
a diameter of the second portion is changed according to a height of the second portion.

18. The method of claim 15, wherein
the connection electrode includes:
a first portion disposed on the first semiconductor layer, and
a second portion disposed on a side surface of the light emitting element rod, and
a diameter of the second portion is substantially constant according to a height of the second portion.

19. The method of claim 15, wherein the light emitting element has at least one of a circular shape, a hexagonal shape, and a rectangular shape in a plan view.

20. The method of claim 15, wherein the connection electrode includes at least one of gold (Au), copper (Cu), tin (Sn), silver (Ag), aluminum (Al), and titanium (Ti).
